(19) United States
(12) Patent Application Publication
(10) Pub. No.: US 2026/0312726 A1
(43) Pub. Date: Oct. 8, 2026

(54) SYSTEMATIC POLAR CODE USING DISTRIBUTED CYCLIC REDUNDANCY CHECK CODING

(71) Applicant: QUALCOMM Incorporated, San Diego, CA (US)

(72) Inventors: Wei YANG, San Diego, CA (US); Kirill IVANOV, La Jolla, CA (US); Thomas Joseph RICHARDSON, South Orange, NJ (US); Jing JIANG, San Diego, CA (US)

(21) Appl. No.: 19/173,330

(22) Filed: Apr. 8, 2025

(51) Int. Cl. H04L 1/00

(52) U.S. Cl. CPC H04L 1/0061; H04L 1/0071

(57) ABSTRACT

This disclosure provides methods, components, devices and systems for systematic polar code using distributed cyclic redundancy check (dCRC) coding. For example, an encoding device may perform a first polar transformation to convert information and parity bits to an intermediate domain. The encoding device may map the converted bits to an intermediate vector and perform a second polar transformation to generate encoded bits in a third domain. The parity bits may be generated based on an inverse interleaver or in accordance with a dCRC function. A decoding device may convert the encoded bits into the intermediate domain. The decoding device may decode a portion of the intermediate vector and determine that the decoded portion does not satisfy a decoding constraint. In such cases, the decoding device may stop decoding the remainder of the encoded bits in the intermediate domain.

### TECHNICAL FIELD

This disclosure relates generally to wireless communication, and more specifically to systems, devices, methods, and techniques associated with systematic polar code using distributed cyclic redundancy check coding.

### DESCRIPTION OF THE RELATED TECHNOLOGY

Communication systems are deployed to provide communication services such as voice, video, packet data, messaging, or broadcast, among others. A communication system may include a wireless communication network (such as a radio access network (RAN)) that supports communication between wireless communication devices such as network entities (such as base stations), client devices (such as one or more user equipments (UEs)), and others. Such devices may communicate with one another using a variety of protocols (such as radio access technologies (RATs)), including those of cellular-based systems such as fourth generation (4G) systems (such as Long Term Evolution (LTE) systems), fifth generation (5G) systems (such as 5G New Radio (5G-NR) systems), and sixth generation (6G) systems. A wireless communication network may support communication by implementing system resources (such as frequency resources, time resources, spatial resources) in accordance with a wireless communication protocol.

### SUMMARY

The systems, methods, and devices of this disclosure each have several innovative aspects, no single one of which is solely responsible for the desirable attributes disclosed herein. The following is a summary of some non-limiting aspects of the disclosure:

A method for wireless communications by an encoding device is described. The method may include generating, using a first polar transformation matrix, a first set of transformed bits based on a set of data bits, computing, based on the first set of transformed bits, a first set of parity bits such that the first set of parity bits satisfy an encoding constraint, mapping the first set of parity bits to first bit locations of an intermediate domain vector and the first set of transformed bits to second bit locations of the intermediate domain vector, the first bit locations preceding the second bit locations, generating, using a second polar transformation matrix, encoded bits based on the intermediate domain vector, and transmitting the encoded bits.

An encoding device for wireless communications is described. The encoding device may include a processing system that includes processor circuitry and memory circuitry that stores code. The processing system may be configured to cause the encoding device to generate, using a first polar transformation matrix, a first set of transformed bits based on a set of data bits, compute, based at least in part on the first set of transformed bits, a first set of parity bits such that the first set of parity bits satisfy an encoding constraint, map the first set of parity bits to first bit locations of an intermediate domain vector and the first set of transformed bits to second bit locations of the intermediate domain vector, the first bit locations preceding the second bit locations, generate, using a second polar transformation matrix, encoded bits based on the intermediate domain vector, and transmit the encoded bits.

Another encoding device for wireless communications is described. The encoding device may include means for generating, using a first polar transformation matrix, a first set of transformed bits based on a set of data bits, means for computing, based on the first set of transformed bits, a first set of parity bits such that the first set of parity bits satisfy an encoding constraint, means for mapping the first set of parity bits to first bit locations of an intermediate domain vector and the first set of transformed bits to second bit locations of the intermediate domain vector, the first bit locations preceding the second bit locations, means for generating, using a second polar transformation matrix, encoded bits based on the intermediate domain vector, and means for transmitting the encoded bits.

A non-transitory computer-readable medium storing code for wireless communications is described. The code may include instructions executable by one or more processors to generate, using a first polar transformation matrix, a first set of transformed bits based on a set of data bits, compute, based at least in part on the first set of transformed bits, a first set of parity bits such that the first set of parity bits satisfy an encoding constraint, map the first set of parity bits to first bit locations of an intermediate domain vector and the first set of transformed bits to second bit locations of the intermediate domain vector, the first bit locations preceding the second bit locations, generate, using a second polar transformation matrix, encoded bits based on the intermediate domain vector, and transmit the encoded bits.

In some examples of the method, encoding devices, and non-transitory computer-readable medium described herein, computing the first set of parity bits may include operations, features, means, or instructions for applying an inverted interleaver to the first set of transformed bits to generate a first set of inverted bits, where the inverted interleaver is an inversion of a first interleaver, the first interleaver based at least in part on a cyclic redundancy check polynomial, and where the first set of parity bits may be based on the first set of inverted bits.

In some examples of the method, encoding devices, and non-transitory computer-readable medium described herein, the encoding constraint includes a cyclic redundancy check polynomial and the first set of parity bits includes one or more cyclic redundancy check bits.

In some examples of the method, encoding devices, and non-transitory computer-readable medium described herein, the intermediate domain vector includes the first set of parity bits in a first portion of the intermediate domain vector and the first set of transformed bits in a second portion of the intermediate domain vector.

In some examples of the method, encoding devices, and non-transitory computer-readable medium described herein, computing the first set of parity bits may include operations, features, means, or instructions for generating a parity check matrix in accordance with an interleaver, where the first set of parity bits may be based on the parity check matrix, an inverted parity check matrix, and the first set of transformed bits.

In some examples of the method, encoding devices, and non-transitory computer-readable medium described herein, the inverted parity check matrix includes an inverted portion of the parity check matrix, the inverted portion corresponding to a quantity associated with the first set of parity bits.

In some examples of the method, encoding devices, and non-transitory computer-readable medium described herein, the encoding constraint includes a function of the first set of parity bits and the first set of transformed bits and satisfying the encoding constraint includes the function satisfying a scalar condition.

In some examples of the method, encoding devices, and non-transitory computer-readable medium described herein, the intermediate domain vector includes the first set of parity bits interleaved with the first set of transformed bits.

A method for wireless communications by a decoding device is described. The method may include receiving a message including a set of encoded bits, decoding the set of encoded bits to obtain a first portion of an intermediate domain vector using a first polar transformation matrix, the intermediate domain vector including a first set of parity bits and a first set of transformed bits, the first set of transformed bits associated with a payload of the message, and refrain from decoding a second portion of the intermediate domain vector based on a first portion of the first set of transformed bits and at least a portion of the first set of parity bits failing to satisfy a decoding constraint.

A decoding device for wireless communications is described. The decoding device may include a processing system that includes processor circuitry and memory circuitry that stores code. The processing system may be configured to cause the decoding device to receive a message including a set of encoded bits, decode the set of encoded bits to obtain a first portion of an intermediate domain vector using a first polar transformation matrix, the intermediate domain vector including a first set of parity bits and a first set of transformed bits, the first set of transformed bits associated with a payload of the message, and refrain from decoding a second portion of the intermediate domain vector based on a first portion of the first set of transformed bits and at least a portion of the first set of parity bits failing to satisfy a decoding constraint.

Another decoding device for wireless communications is described. The decoding device may include means for receiving a message including a set of encoded bits, means for decoding the set of encoded bits to obtain a first portion of an intermediate domain vector using a first polar transformation matrix, the intermediate domain vector including a first set of parity bits and a first set of transformed bits, the first set of transformed bits associated with a payload of the message, and means for refrain from decoding a second portion of the intermediate domain vector based on a first portion of the first set of transformed bits and at least a portion of the first set of parity bits failing to satisfy a decoding constraint.

A non-transitory computer-readable medium storing code for wireless communications is described. The code may include instructions executable by one or more processors to receive a message including a set of encoded bits, decode the set of encoded bits to obtain a first portion of an intermediate domain vector using a first polar transformation matrix, the intermediate domain vector including a first set of parity bits and a first set of transformed bits, the first set of transformed bits associated with a payload of the message, and refrain from decoding a second portion of the intermediate domain vector based on a first portion of the first set of transformed bits and at least a portion of the first set of parity bits failing to satisfy a decoding constraint.

In some examples of the method, decoding devices, and non-transitory computer-readable medium described herein, decoding the set of encoded bits may include operations, features, means, or instructions for decoding the set of encoded bits to obtain the first set of parity bits and decoding the first portion of the first set of transformed bits, where the first portion of the first set of transformed bits fails to satisfy the decoding constraint.

In some examples of the method, decoding devices, and non-transitory computer-readable medium described herein, decoding the set of encoded bits may include operations, features, means, or instructions for decoding the set of encoded bits to obtain the first portion of the first set of transformed bits and decoding a first portion of the first set of parity bits corresponding to the first portion of the first set of transformed bits, where the first portion of the first set of transformed bits fails to satisfy the decoding constraint.

Some examples of the method, decoding devices, and non-transitory computer-readable medium described herein may further include operations, features, means, or instructions for refraining from generating a decoded domain vector using a second polar transformation matrix and the intermediate domain vector based on the first set of transformed bits and at least the portion of the first set of parity bits failing to satisfy the decoding constraint.

### BRIEF DESCRIPTION OF THE DRAWINGS

FIG. 1 shows an example of a wireless communication system.

FIG. 2 shows an example of a signaling configuration that supports systematic polar code using distributed cyclic redundancy check coding.

FIG. 3 shows an example of a systematic polar coding procedure that supports systematic polar code using distributed cyclic redundancy check coding.

FIG. 4 shows an example of a systematic polar coding procedure that supports systematic polar code using distributed cyclic redundancy check coding.

FIG. 5 shows an example of a process flow that supports systematic polar code using distributed cyclic redundancy check coding.

FIG. 6 shows a block diagram of a processing system that supports systematic polar code using distributed cyclic redundancy check coding.

FIG. 7 shows a diagram of a system including a device that supports systematic polar code using distributed cyclic redundancy check coding.

FIG. 8 shows a block diagram of a processing system that supports systematic polar code using distributed cyclic redundancy check coding.

FIG. 9 shows a diagram of a system including a device that supports systematic polar code using distributed cyclic redundancy check coding.

FIGS. 10 and 11 show flowcharts illustrating methods that support systematic polar code using distributed cyclic redundancy check coding.

Details of aspects and advantages of the subject matter in this disclosure are set forth in the drawings and accompanying descriptions. Like reference numbers and designations in the various drawings indicate like elements.

### DETAILED DESCRIPTION

A communication system may include a radio access network (RAN) that supports wireless communication. Communication of a RAN may be performed in accordance with one or more radio access technologies (RATs), including 4G, 5G, or 6G, among others, including technologies not explicitly mentioned herein. A RAT may employ access technologies (such as multiplexing technologies) including code division multiple access (CDMA), time division multiple access (TDMA), frequency division multiple access (FDMA), orthogonal FDMA (OFDMA), single-carrier FDMA (SC-FDMA), time division synchronous code division multiple access (TD-SCDMA), or discrete Fourier transform spread orthogonal frequency division multiplexing (DFT-S-OFDM), among others. A RAT may support one or more service types, including machine type communication (MTC), massive MTC (mMTC), Internet of Things (IoT), narrowband IoT (NB-IoT), reduced capability (RedCap), enhanced mobile broadband (eMBB), ultra-reliable low-latency communication (URLLC), or public safety, among others.

To support these and other target verticals, a communication system (such as a RAN) may be designed to implement one or more of a modularized functional infrastructure, a disaggregated and service-based network architecture, network function virtualization, network slicing, multi-access edge computing, spatial processing or multipath techniques, IoT or RedCap device connectivity and management, industrial connectivity, licensed and unlicensed spectrum access, sidelink or other device-to-device (D2D) direct communication (such as vehicle-to-everything (V2X)), frequency spectrum expansion, overlapping spectrum use, small cell deployments, non-terrestrial network (NTN) deployments, device aggregation, advanced duplex communication (such as sub-band full-duplex (SBFD)), multiple-subscriber implementations, high-precision positioning, radio frequency (RF) sensing, network energy savings (NES), low-power signaling and radios, or artificial intelligence or machine learning (AI/ML), among other examples.

The foregoing and other technological improvements may support use cases such as voice calls, messaging, data transfer, streaming, wireless data centers, extended reality (XR) and metaverse applications, vehicle connectivity, holographic and mixed reality communication, autonomous and collaborative robots, sensing networks, gesture monitoring, human-brain interfacing, digital twin applications, asset management, and universal coverage using non-terrestrial or aerial platforms, among other examples. As the demand for connectivity continues to increase, further improvements may be implemented, and other RATs, including 6G and beyond, may be introduced to enable new applications and use cases. The systems, methods, and devices described herein may enable one or more of the foregoing technologies or new technologies or support one or more of the foregoing use cases or new use cases.

In some wireless communications systems, wireless devices may implement polar codes to approach channel capacity in binary wireless channels. For polar codes, a non-systematic polar code may be converted to a systematic polar code by calling the non-systematic encoding twice. For example, an encoding device may perform a first polar transformation to convert information bits into an intermediate domain, then may perform a second polar transformation to convert the bits from the intermediate domain into systematic polar code. Additionally, wireless devices may implement error correction techniques, such as cyclic redundancy check (CRC) codes. In some cases (e.g., downlink polar code used for control information over a control channel), the encoding device may implement distributed cyclic redundancy check (dCRC) codes, where CRC bits are interleaved with (e.g., inserted between) information bits in an encoded message. Because of this, each CRC bit in the message may be based on the preceding information bits in the message and may be independent of the following information bits in the message. However, it may be difficult to support dCRC in systematic polar codes because for systematic polar coding, the CRC bits are inserted at the beginning of the set of reliable bit locations of the polar code instead of being interleaved with the payload.

Various aspects of the present disclosure are related to systematic polar code using distributed cyclic redundancy check coding. In some examples, an encoding device may perform a first polar transformation to convert a set of data bits to an intermediate domain. The encoding device may map converted information bits and one or more parity bits included in the set of data bits to the intermediate domain and perform a second polar transformation to generate encoded bits in a third domain. In some cases, the parity bits may be CRC bits and the encoding device may generate the CRC bits based on an inverse interleaver. In some other cases, the parity bits may be generated such that an array that combines the parity bits and the converted information bits satisfy a CRC function.

A decoding device may decode an encoded message by performing a first polar transformation to convert the encoded bits into an intermediate domain. In some cases, the parity bits (e.g., CRC bits) may be located before the information bits, and the decoding device may decode one or more CRC bits located at the beginning of the intermediate domain. After decoding the CRC bits, the decoding device may decode each information bit. In some other cases, the parity bits may be interleaved with the information bits, and the decoding device may decode corresponding portions of the parity bits and CRC bits. In both cases, the decoding device may stop decoding the encoded message in the intermediate domain if a set of information bits and a corresponding parity bit fail to satisfy a CRC constraint.

Particular aspects of the subject matter described in this disclosure can be implemented to realize one or more of the following potential advantages. In some examples, by supporting dCRC for use with systematic polar codes, the described techniques can be used to reduce power consumption associated with transmissions between wireless devices. For example, a decoding device that supports dCRC for use with systematic polar codes may be able to terminate decoding of an encoded message early. In some cases, the decoding device may refrain from performing multiple polar transforms on the encoded message, which may further reduce decoding complexity and free up resources at the decoding device.

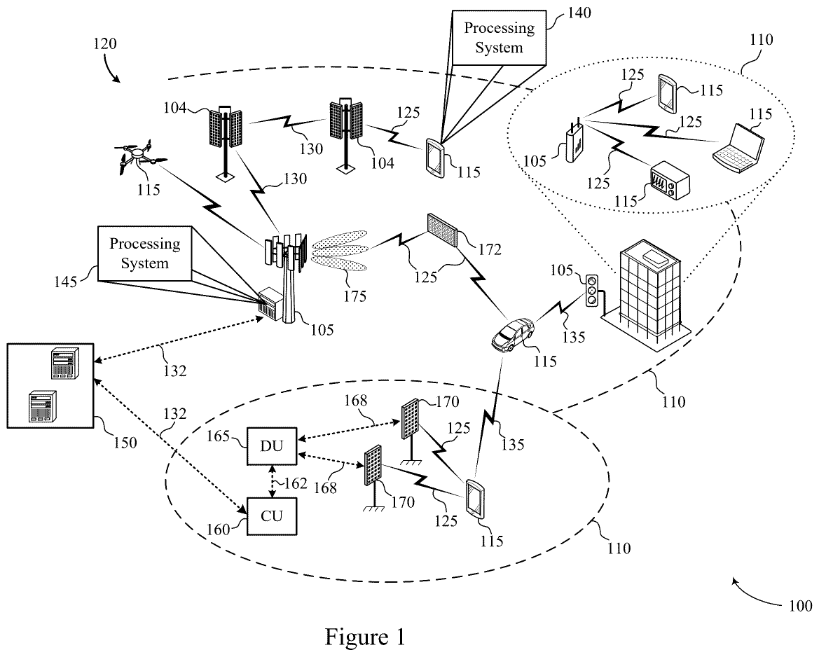

FIG. 1 shows an example of a wireless communication system 100. The wireless communication system 100 includes a core network 150 and a RAN 120 that support communication with one or more devices, such as UEs 115. A RAN 120 may include one or more network entities 105 configured to support wireless communication with the UEs 115.

The wireless communication system 100 may support communication among network entities 105 and UEs 115 in accordance with a layered protocol stack. For example, in a user plane, communication at a bearer layer, a Packet Data Convergence Protocol (PDCP) layer, or Service Data Adaption Protocol (SDAP) layer may be Internet Protocol (IP)-based. A Radio Link Control (RLC) layer may perform packet segmentation and reassembly to communicate via logical channels. A Medium Access Control (MAC) layer may perform priority handling and multiplexing of logical channels into transport channels. A MAC layer also may implement error detection techniques, error correction techniques, or retransmissions. In a control plane, a Radio Resource Control (RRC) layer may provide establishment, configuration, and maintenance of an RRC connection between UEs 115 and a network entity 105 or a core network 150, supporting radio bearers for user plane data. A Physical (PHY) layer may map transport channels to physical channels.

A core network 150 may support user authentication, access authorization, tracking, IP connectivity, and other access, routing, or mobility functions (such as via network entities 105). A core network 150 may be a 5G core (5GC) or 6G core (6GC), and may include at least one control plane entity that manages access and mobility and at least one user plane entity that routes packets or interconnects to external networks (such as a serving gateway (S-GW), a Packet Data Network (PDN) gateway (P-GW), a user plane function (UPF)).

A network entity 105 may support wireless communication in accordance with one or more coverage areas 110, and may be referred to as a network element, a network node, a RAN node, or network equipment, among other nomenclature. One or more of the network entities 105 may include or may be referred to as a base station. Depending on its capabilities, a base station may be referred to as a NodeB, an eNodeB (eNB), a next-generation NodeB or giga-NodeB (either of which may be referred to as a gNB), a 5G NB, a 6G NB, a next-generation eNB (ng-eNB), a Home NodeB, a Home eNodeB, or other suitable terminology. The wireless communication system 100 may include a heterogeneous network in which different types of network entities 105 support communication for one or more coverage areas 110 using the same or different RATs.

In some examples, a network entity 105 may be implemented in an aggregated (such as monolithic, standalone) architecture, which may utilize a protocol stack that is physically or logically integrated within one network entity 105 (such as a single physical RAN node). In some other examples, a network entity 105 may be implemented in a disaggregated architecture, which may utilize a protocol stack that is physically or logically distributed among multiple network entities 105, including in an integrated access and backhaul (IAB) network, an open RAN (O-RAN), or a virtualized RAN (vRAN). In a disaggregated architecture, a network entity 105 may include or be referred to as one or more of a central unit (CU) (such as CU 160), a distributed unit (DU) (such as DU 165), a radio unit (RU) (such as RU 170), or a combination thereof. The wireless communication system 100 may also implement a service-based architecture that provides a modular framework in which control plane functionality and common data repositories may be delivered through a set of interconnected network functions (NFs) that may access services of other NFs.

UEs 115 may be located in a coverage area 110 of one or more network entities 105, and may include or be referred to as an access terminal, a mobile station, a client device, or a subscriber unit. A UE 115 may be, include, or be coupled with a cellular phone, a wireless modem, a tablet device, a laptop computer, a wireless local loop (WLL) station, a camera, a medical or biometric device, a wearable device, a gaming device, an entertainment device, an XR device, a vehicular component or sensor, a smart meter or sensor, industrial manufacturing equipment, a Global Positioning System (GPS) or other positioning device, a robot or other device implementing artificial intelligence, a UE function of a network node, or any other wireless communication device or function that may communicate using a wireless medium.

The wireless communication system 100 may support various types of communication links among devices. For example, wireless communication between a network entity 105 and a UE 115 may be supported using one or more of a communication link 125 (such as a Uu interface), which may include downlink communication from a network entity 105 to a UE 115, uplink communication from a UE 115 to a network entity 105, or both. Direct wireless communication between UEs 115 may be supported using a communication link 135 (such as a device-to-device (D2D) communication link, a sidelink, a PC5 interface).

Communication between a network entity 105 and a core network 150 may be supported using a backhaul link 132 (such as an S1, N2, N3, NG, or other interface). In some implementations, communication between network entities 105 may be supported using a backhaul link 132 (such as an X2, Xn, or other interface) either directly (such as directly between network entities 105) or indirectly (such as via a core network 150). In some implementations (such as in a disaggregated architecture), communication between a CU 160 and a DU 165 may be supported using a midhaul link 162, and communication between a DU 165 and an RU may be supported using a fronthaul link 168. A backhaul link 132, a midhaul link 162, a fronthaul link 168, or any combination thereof may be or include one or more wired links (such as an electrical link, an optical fiber link) or one or more wireless links (such as a radio link, a wireless optical link), among other examples or combinations thereof. Wireless backhaul, midhaul, or fronthaul may be implemented via one or more IAB nodes 104, which may act as a relay using resources of an IAB donor network entity 105 (such as via a wireless link 130).

The wireless communication system 100 may include one or more of a relay 172 that may steer or reflect signals transmitted by other entities, which may support any of the described communication links. A relay 172 may include active elements or passive elements, and may be in the form of a reconfigurable intelligent surface (RIS). An RIS may include tunable reflecting antenna arrays or metasurfaces, which may be used to enhance coverage or efficiency in multipath environments.

Network entities 105 and UEs 115 each may include one or multiple antennas. Multiple antennas of such devices may be used to employ techniques such as transmit diversity, receive diversity, MIMO communication, or beamforming, and may be organized or structured as one or more antenna panels, one or more antenna groups, one or more sets of antenna elements, or one or more antenna arrays, among other examples. As used herein, the term “antenna” may refer to one or more antennas, one or more antenna panels, one or more antenna groups, one or more sets of antenna elements, or one or more antenna arrays. The term “antenna panel” may refer to a group of antennas (such as antenna elements) arranged in an array or panel, which may facilitate beamforming by manipulating parameters associated with the group of antennas. In some implementations, an antenna panel may support RF beamforming for a signal transmitted or received via an antenna port. The term “antenna module” may refer to circuitry including one or more antennas as well as one or more other components (such as filters, amplifiers, processors, beamformers) associated with integrating the antenna module into a device such as a network entity 105 or a UE 115.

Beamforming, such as directional transmission or directional reception, is a signal processing technique that may be used at a transmitting device or a receiving device (such as at a network entity 105, at a UE 115) to shape or steer a beam 175 (such as an antenna beam, a transmit beam, a receive beam) along a spatial path (such as along a direction), which may include one or more paths between a transmitting device and a receiving device. Beamforming may be achieved by combining signals communicated via multiple antenna elements of an antenna array such that signals propagating along some orientations (such as relative to the antenna array) experience constructive interference while others may experience destructive interference. Adjustments of signals communicated via the antenna elements may include a transmitting device or a receiving device applying phase offsets, amplitude offsets, or both to signals carried via (such as transmitted by, received by) antenna elements of the device, which may be defined by a beamforming weight set associated with a particular orientation (such as relative to the antenna array of the device).

Communication resources of the wireless communication system 100 (such as of a RAN 120) may refer to a resource in the frequency domain (such as a frequency resource, an RF resource), a resource in the time domain (such as a time resource), a resource in the spatial domain (such as a spatial resource, a spatial layer), or a combination thereof. The wireless communication system 100 may leverage orthogonality of such resources to convey different communications to or from different devices (such as for a communication link 125, for a communication link 135, for unicast communication, for multicast communication, for broadcast communication).

A frequency resource may refer to a frequency or range of frequencies (such as a bandwidth, a frequency channel) of a frequency band implemented for wireless communication. For example, a frequency resource may refer to a resource of a lower frequency band (such as Frequency Range 1 (FR1), between 425 MHz and 7.125 GHz), a mid-band (such as Frequency Range 3 (FR3), between 7.125 GHz and 24.25 GHz), or an upper frequency band (such as Frequency Range 2 (FR2), between 24.25 GHz and 71 GHz). Communication in the upper frequency band may be referred to as millimeter wave (mmW) communication, and communication above an upper frequency band (such as between mmW and THz frequencies, between 100 GHz and 1 THz) may be referred to as sub-Terahertz (sub-THz) communication.

A frequency resource may refer to a “carrier” (such as a frequency channel), or portion thereof, and a carrier bandwidth may be referred to as a “system bandwidth.” A carrier may be subdivided in the frequency domain, including into subcarriers, bandwidth parts (BWPs), or both. For example, a resource block (RB), such as a physical resource block (PRB), may be defined in accordance with a set of subcarriers (such as twelve consecutive subcarriers in the frequency domain), and a BWP may be configured in accordance with a set of RBs (such as a set of contiguous RBs).

A frequency resource may be configured to carry either downlink communication or uplink communication (such as in a frequency division duplexing (FDD) configuration), or may be configured to carry both downlink and uplink communication (such as in a time division duplexing (TDD) configuration, in a sub-band full duplex (SBFD) configuration). One or more numerologies for a carrier may be supported, each associated with a subcarrier spacing (SCS) and a cyclic prefix (CP). Supported numerologies may vary by frequency range (such as FR1, FR2, FR3), and a carrier may be divided into portions (such as BWPs) having the same or different numerologies. BWPs may be configured as uplink BWPs or downlink BWPs (such as by a network entity 105), including in response to network conditions (such as to allocate uplink and downlink BWPs in response to traffic conditions), device capability (such as allocating BWPs with a greater quantity of RBs to UEs 115 with relatively higher capabilities), or both. A UE 115 may be configured with a set of multiple BWPs (such as a set of uplink BWPs, a set of downlink BWPs, or both), and a single BWP of a set (such as an active UL BWP, an active DL BWP, or both) may be active at a given time, such that communication of a UE 115 is supported by active BWP(s).

A time resource may refer to a duration of a frame (such as a radio frame, a frame structure), or portion thereof. For example, a frame may span a duration of 10 ms, and each frame may be identified by a system frame number (SFN). A frame may be subdivided in the time domain, including into subframes, slots, mini-slots, or a combination thereof. Slots or mini-slots may each include a respective quantity of symbols (such as symbol durations, symbol periods, OFDM symbols), which may be a function of a configured CP. A duration of a symbol is a function of the SCS or frequency band of operation.

A spatial resource may refer to an antenna, an antenna direction, an antenna port, a signal direction (such as a beamforming direction), or other resource that supports spatial orthogonality. A device (such as a network entity 105, a UE 115) may perform communications of a given frequency resource and time resource with a single spatial resource (such as communication without regard to spatial orthogonality). Additionally, or alternatively, a device may implement multiple spatial resources to support multiple signal streams using resources that are overlapping in the time and frequency domains (such as to support MIMO techniques).

Signals of the wireless communication system 100 (such as of a RAN 120) may be communicated using one or more resource elements (REs), and an RE may refer to a resource that corresponds to one subcarrier in the frequency domain and one symbol in the time domain. An RE may be used to convey a modulation symbol corresponding to one or more bits of information (such as of a physical channel, of a reference signal) in accordance with a modulation scheme. For example, a quadrature phase shift keying (QPSK) or quadrature amplitude modulation (QAM) technique may be implemented to communicate one or more bits that are distinguished in accordance with phase components, amplitude components, or both of a signal conveyed using a RE. A quantity of bits carried by an RE may depend on an order of the modulation scheme, and a relatively higher order may correspond to a relatively higher rate of communication. A device may support communication of REs using multiple subcarriers concurrently by implementing multi-carrier modulation (MCM) techniques such as orthogonal frequency division multiplexing (OFDM) or discrete Fourier transform spread OFDM (DFT-S-OFDM), among others.

Physical channels may carry information using modulation symbols conveyed by corresponding REs. Physical shared channels (such as for communicating user data) may include a physical downlink shared channel (PDSCH) for communicating user data in a downlink direction and a physical uplink shared channel (PUSCH) for communicating user data in an uplink direction. Physical control channels (such as for managing communication via physical channels) may include a physical downlink control channel (PDCCH) for communicating downlink control information (DCI) and a physical uplink control channel (PUCCH) for communicating uplink control information (UCI). A network entity 105 may indicate (such as schedule, allocate) communication resources for a UE 115 using DCI, including indicating downlink resources of a PDSCH (such as in accordance with a downlink grant), uplink resources of a PUSCH (such as in accordance with an uplink grant), or a combination thereof. A control region (such as a control resource set (CORESET)) for a physical control channel may be configured in accordance with a pattern of REs in the time and frequency domains, and one or more control regions may be configured for a set of UEs. A UE 115 may monitor control regions for control information according to one or more search space sets, which may include a common search space set (such as for sending control information to one or more UEs 115), UE-specific search space sets (such as for sending control information to a UE 115), or a combination thereof. A physical broadcast channel (PBCH) may be used to broadcast parameters to UEs 115 to synchronize with a network entity 105 and establish communications (such as to establish a communication link 125).

Reference signals may be communicated to establish reference characteristics (such as a frequency reference, a temporal reference, a spatial reference, a signal quality reference) between devices of a RAN 120, which may support communication using physical channels. Reference signals communicated between network entities 105 and UEs 115 may include synchronization signals (such as a primary synchronization signal (PSS), a secondary synchronization signal (SSS)) that support temporal synchronization, channel state information-reference signals (CSI-RSs) that support evaluating downlink channel characteristics, sounding reference signals (SRSs) that support evaluating uplink channel characteristics, demodulation reference signals (DMRSs) that support demodulation, or phase tracking reference signals (PTRSs) for evaluating oscillator characteristics, among others. Network entities 105 and UEs 115 may receive and measure transmitted reference signals to support one or more of these and other functions.

Devices of the wireless communication system 100 may be configured to support one or more aspects of the described techniques for systematic polar code using dCRC coding. For example, a UE 115 may include a processing system 140, and a network entity 105 may include a processing system 145, each of which may be configured to cause the respective device to perform (such as being configured as means for performing) one or more of the described operations. By configuring a processing system 140, a processing system 145, or a combination thereof in accordance with the described techniques, the communication system 100 (such as the RAN 120) may support reduced latency and reduced power consumption associated with decoding systematic polar codes. For example, the described techniques may support early decoding termination at a decoding device if the decoding device determines that a portion of an encoded message fails to satisfy a decoding constraint.

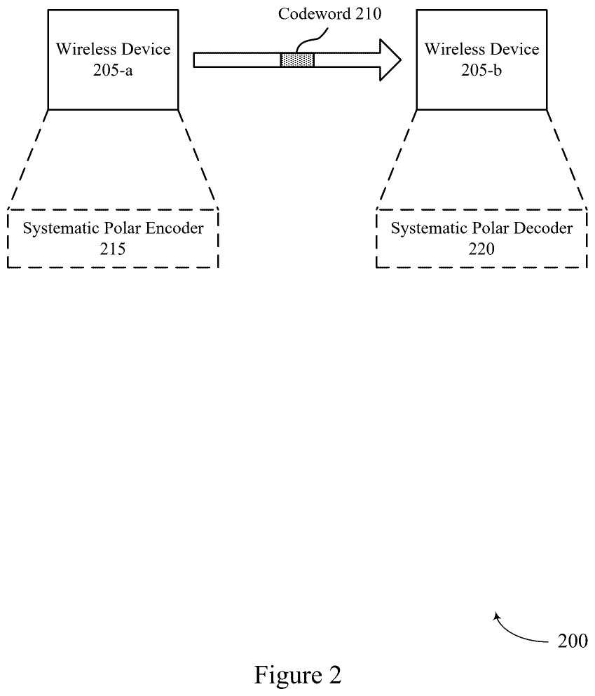

FIG. 2 shows an example of a signaling configuration 200 that supports systematic polar code using distributed cyclic redundancy check coding. The signaling configuration 200 may implement or be implemented by aspects of the wireless communications system 100. For example, the signaling configuration 200 may illustrate and describe communications between a wireless device 205-a and a wireless device 205-b, which may be examples of network entities 105, UEs 115, or one or more other devices, as described with reference to FIG. 1. In some examples, the signaling configuration 200 may support the use of polar codes for wireless communications to achieve wireless channel capacity over binary channels with polynomial complexity. Polar coding may involve mapping (e.g., assigning) bits to different bit-channels and encoding the bits such that certain bit-channels (e.g., polar channels) are polarized to an increase reliability, while other bit-channels are polarized to a decreased reliability. Devices (e.g., the wireless device 205-a, the wireless device 205-b) may sort the bit-channels by levels of reliability, such as by most reliable bit-channel to least reliable bit-channel.

As an example, an encoding device (e.g., a transmitting device, the wireless device 205-a) may implement a polar code using a matrix that polarizes copies of a channel into subchannels (which may be referred to as bit channels) that are either relatively noisy (corresponding to decreased reliability) or relatively noiseless (corresponding to increased reliability). Information bits may be mapped to the relatively noiseless bit channels, and frozen bits (e.g., bits that may be known by both the transmitting wireless communication device and a receiving wireless communication device) may be mapped to the relatively noisy bit channels. The transmitting device may transmit a codeword 210 in accordance with the mapping to the respective bit channels.

Polar codes may be linear codes that are non-systematic, and may be turned into a systematic code (e.g., polar codes may be encoded systematically). In some examples, a systematic polar code may refer to a polar code that includes information bits that transparently appear as part of the codeword. Systematic polar codes may be more capable of utilizing additional information (e.g., side information) about the source code than non-systematic polar codes, which may be useful for implementation in data-driven systems or data-driven code designs. In some examples, the wireless device 205-a and the wireless device 205-b may perform systematic polar coding according to a systematic polar coding procedure.

The systematic polar coding procedure may involve converting a non-systematic linear code into a systematic linear code. For example, the wireless device 205-a may convert the non-systematic linear code into the systematic linear code by inverting at least a portion of a generator matrix. Additionally, or alternatively, the wireless device 205-a may convert the non-systematic linear code into the systematic linear code by performing non-systematic encoding twice. For example, the wireless device 205-a may implement systematic polar encoding by calling non-systematic polar encoding twice. As described herein, performing the non-systematic encoding twice to implement the systematic polar encoding may refer to performance of a first polar coding transform and a second polar coding transform. For example, the wireless device 205-a may use a systematic polar encoder 215 to perform the systematic polar encoding procedure including the first polar coding transform and the second polar coding transform and generate a codeword 210.

By performing systematic polar coding, a location of information bits in the codeword 210 may be the same as a location of the information bits prior to the systematic polar coding procedure (e.g., prior to the first polar coding transform and the second polar coding transform). In some examples, for the location of the information bits to be the same before and after the systematic polar coding procedure, a sequence of the information bits may satisfy a condition (e.g., algebraic properties) associated with generating a systematic codeword 210 (e.g., in which the information bits are transparent). To decode a codeword 210 encoded in accordance with the systematic polar coding procedure, the wireless device 205-b may decode the polar code resulting from the second polar transform with a conventional decoder (e.g., successive cancellation list (SCL) decoder), decode the polar code resulting from the first polar transform, and convert (e.g., via the first polar transform) decoded bits of the polar code resulting from the first polar transform to obtain the information bits.

A decoding device (e.g., the wireless device 205-b) may receive the codeword 210 encoded via the systematic polar encoder 215. The wireless device 205-b may decode the codeword 210 via (e.g., using, by applying, or the like) a systematic polar decoder 220. Decoding the codeword 210 via the systematic polar decoder 220 may involve a systematic polar decoding procedure in which the wireless device 205-b performs one or more polar transforms to decode the codeword 210. For example, the wireless device 205-b may perform the second polar coding transform on the bits of the codeword, and then perform the first polar coding transform to identify the bits inserted to one or more bit channels (e.g., originally). In other words, the systematic polar decoding procedure may correspond to a reverse order of one or more operations in the systematic polar encoding procedure.

In some examples, the wireless device 205-a may include one or more error check bits (e.g., parity bits) in the codeword 210 such that the wireless device 205-b may determine an integrity of information in the codeword 210. For example, the wireless device 205-a may include one or more cyclic redundancy check (CRC) bits. The wireless device 205-b may verify an integrity of information included in the codeword 210 based on the included one or more CRC bits. For example, by including the one or more CRC bits, the wireless device 205-b may improve a performance level associated with polar coding. In examples in which the wireless device 205-a includes the one or more CRC bits, a bit sequence b₀, . . . , bₙ₋₁ may satisfy a CRC constraint if Equation 1 below includes a CRC polynomial g(x) as a factor.

$$\\ \begin{matrix}{{\sum }^{n - 1}}_{i = 0} {b}_{i} {x}^{n - 1 - i} & ( 1 )\end{matrix}$$

Additionally, in some examples the wireless device 205-a and the wireless device 205-b may support distributed CRC (dCRC) for polar codes. In dCRC, the CRC bits may be interleaved with the information bits prior to mapping the CRC bits and the information bits in accordance with performing with the second polar coding transform. The location of each CRC bit may be selected such that any particular CRC bit depends on the preceding information bits in the sequence of information bits and is independent of subsequent information bits in the sequence of information bits. An encoding device (e.g., the wireless device 205-a) may implement dCRC using a pre-coding interleaver that interleaves (e.g., combines, distributes) the CRC bits and the information bits such that the sequence of interleaved information bits and CRC bits satisfies a dCRC condition.

Implementation of dCRC may support early decoding termination at the wireless device 205-b, which may support power saving at the wireless device 205-b. For example, the wireless device 205-b may decode a portion of the codeword 210 that includes a portion of the information bits of the codeword 210 and a first CRC bit of the codeword 210. If the wireless device 205-b determines that the decoded portion of the information bits does not satisfy the dCRC constraint associated with the first CRC bit, the wireless device 205-b may refrain from decoding the remainder of the codeword 210. In some examples, the wireless device 205-b may begin decoding the codeword 210 by performing decoding in accordance with at least a portion of the second polar coding transform. However, in cases where the wireless device 205-b terminates decoding of the codeword 210 early, the wireless device 205-a may refrain from performing the first polar coding transform (e.g., to save power).

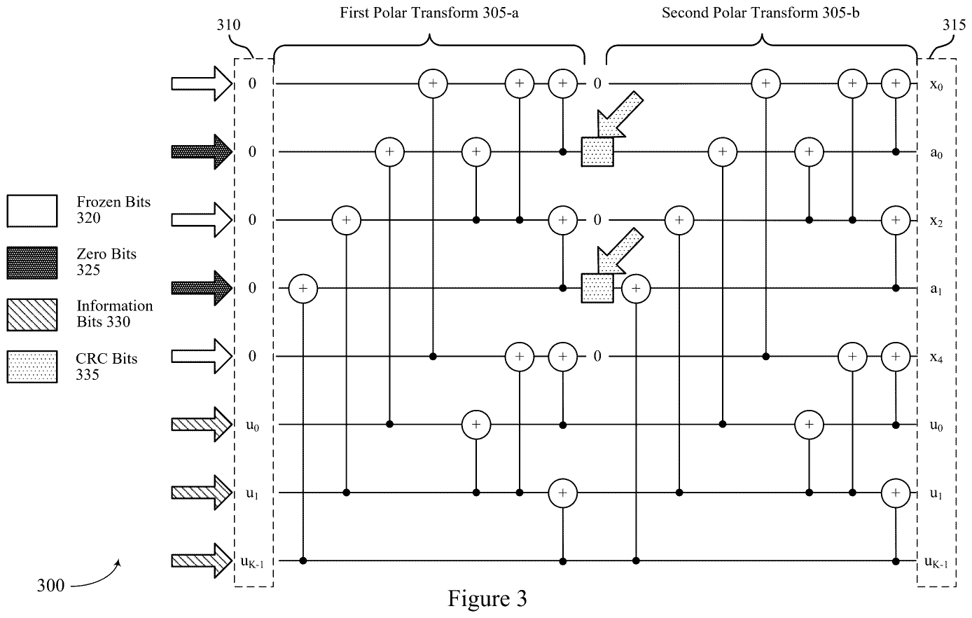

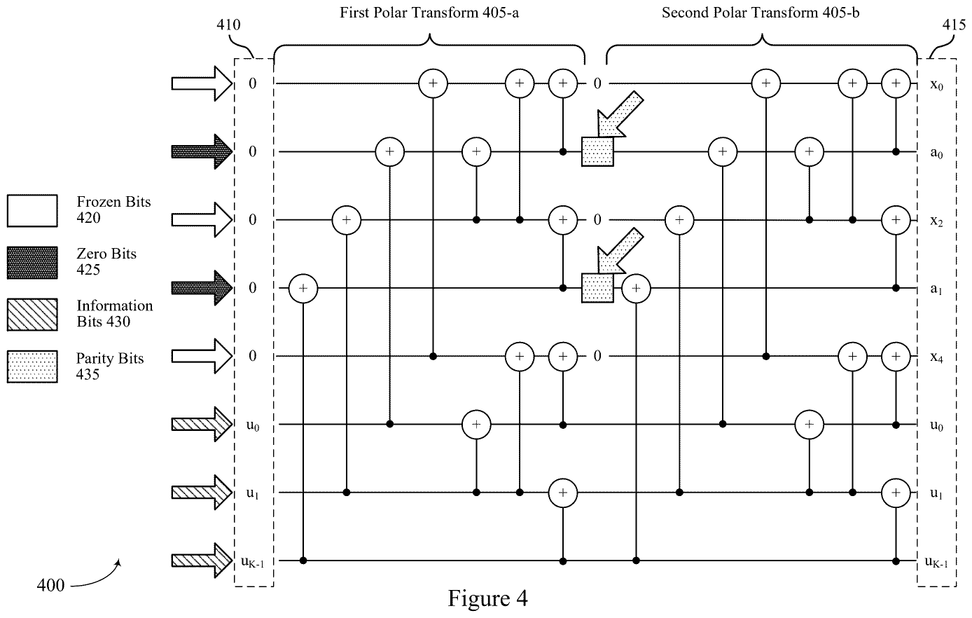

Various aspects of the present disclosure are related to systematic polar codes for dCRC coding. In some examples, to support the inclusion of CRC bits in the codeword 210, the wireless device 205-a may perform systematic polar coding procedures described in further detail elsewhere herein, including with reference to FIGS. 3 through 5. The wireless device 205-a may perform a systematic polar coding procedure based on inserting one or more parity bits in the codeword 210. In some examples, the wireless device 205-a may perform a systematic polar coding procedure with dCRC by computing the parity bits in accordance with a CRC polynomial, which is described in further detail herein with reference to FIG. 3. In such cases, the wireless device 205-a may compute the parity bits (e.g., CRC bits) using an inverted interleaver that is based on a CRC polynomial (e.g., based on a CRC constraint). In some other examples, the wireless device 205-a may perform a systematic polar coding procedure with dCRC by computing the parity bits such that the bit sequence mapped to the second polar coding transform satisfies a dCRC constraint, which is described in further detail herein with reference to FIG. 4.

FIG. 3 shows an example of a systematic polar coding procedure 300 that supports systematic polar code using distributed cyclic redundancy check coding. The systematic polar coding procedure 300 may implement, or be implemented by, aspects of the wireless communications system 100, the signaling configuration 200, or both. For example, the systematic polar coding procedure 300 may be implemented by an encoding device and a decoding device, such as the wireless device 205-a and the wireless device 205-b as described with reference to FIG. 2. In some examples, the wireless device may perform a first polar transform 305-a on a set of data bits 310 to generate a first set of transformed bits. The wireless device may perform a second polar transform 305-b on the first set of transformed bits to calculate a set of encoded bits 315.

As used herein, bits prior to the first polar transform 305-a (e.g., pre-transformed bits, the set of data bits 310) may belong to a first domain (e.g., the U domain). Bits in between the first polar transform 305-a and the second polar transform 305-b may belong to a second domain (e.g., the Z domain). Finally, bits after both the first polar transform 305-a and the second polar transform 305-b (e.g., the set of encoded bits 315) may belong to a third domain (e.g., the X domain). The set of data bits 310 may include one or more frozen bits 320, one or more zero bits 325, and one or more information bits 330, and the set of encoded bits 315 may include one or more frozen bits 320, one or more CRC bits 335, and one or more information bits 330. For example, a bit sequence u₀, u₁, u_{K-1} may correspond to information bits 330. In the example of FIG. 3, a wireless device may compute the CRC bits 335 based on the first set of transformed bits.

The wireless device may apply the first polar transform 305-a to the set of data bits 310. For example, the wireless device may provide the set of data bits 310 as an input to a first generation matrix to generate the first set of transformed bits. To apply the first polar transform 305-a, the wireless communication device may identify bit channels and map the set of data bits 310 (e.g., the frozen bits 320, the zero bits 325, the information bits 330) to the identified bit channels. As used herein, “bit channels” may refer to or be used interchangeably with “bit locations.” For example, the wireless communication device may determine a reliability level associated with each bit channel of multiple bit channels and may order the multiple bit channels from a least reliable bit channel to a most reliable bit channel. The wireless communication device may identify a first set of bit channels, A, of the multiple bit channels. For example, the wireless communication device may identify a first set of bit channels A, of the multiple bit channels as bit channels having highest reliability levels for the first polar transform 305-a. The first set of bit channels may include a quantity K+L bit channels, where K may correspond to the quantity of information bits 330 and L may correspond to a quantity of CRC bits 335.

The first set of bit channels may include information bit channels and parity bit channels. For example, the wireless communication device may select a first subset (e.g., one or more first bit channels) of the first set of bit channels to be information bit channels and select a second subset (e.g., one or more second bit channels) of the first set of bit channels to be parity bit (e.g. CRC bit) channels, where B refers to the CRC bit channels (e.g., to which CRC bits are mapped to) and A refers to the first set of bit channels. The second subset, B, may correspond to a quantity of bit channels having smallest indices according to a natural ordering of indices of the multiple bit channels. In other words, a set B representing a subset of the set A to which CRC bits 335 are to be mapped may include L bit channels (e.g., locations) with smallest indices in the set A. Alternatively, the second subset, B, may correspond to a quantity of bit channels having lowest reliability levels (e.g., according to the polar reliability sequence) in the first set of bit channels. A remaining set of bit channels (e.g., Ā), such as a second set of bit channels, may be frozen bit channels corresponding to frozen bits 320. For example, the second set of bit channels A including the frozen bit channels may correspond to bit channels having lowest reliability levels relative to the other bit channels.

The wireless communication device may map the information bits 330 to the first subset of the first set of bit channels corresponding to the information bit channels. For example, the wireless communication device may place the K information bits 330 in A\B (e.g., a subset of A including elements in A that are not in B) prior to the first polar transform 305-a (e.g., in a first domain). Additionally, the wireless communication device may set bits (e.g., zero bits 325 and frozen bits 320, respectively) in the second subset of the first set of bit channels (e.g., corresponding to the CRC bit channels) and in the second set of bit channels (e.g., corresponding to the frozen bit channels) to zero prior to the first polar transform 305-a. In other words, the wireless communication device may set bits in Ā and B to zero.

The wireless communication device may apply the first polar transform 305-a to the bits mapped to the first set of bit channels and the second set of bit channels. For example, the wireless communication device may convert the bits from the first domain (e.g., a U domain) to a second domain (e.g., a Z domain) via the first polar transform 305-a. The bits transformed according to the first polar transform 305-a may be denoted as z (e.g., z₀, . . . , z_{K-1}). After performing the first polar transform 305-a, the wireless communication device may set the bits in the second set of bit channels (e.g., in Ā) to zero (e.g., insert zero bits 325). The bits in the first subset of the first set of bit channels (e.g., in A\B) may be unchanged after the first polar transform 305-a. For example, the first set of transformed bits in z the locations in set A\B after the polar transform are unchanged prior to the second polar transform 305-b.

The wireless communication device may generate the CRC bits 335 to be inserted after the first polar transform 305-a and prior to the second polar transform 305-b. The CRC bits 335 may be computed based on the first set of transformed bits z. In some examples, the wireless device may apply an inverse interleaver π₁⁻¹(⋅) on the first set of transformed bits z to obtain a first set of K inverted bits \tilde{z} (e.g., \tilde{z}₀, . . . , \tilde{z}_{K-1}) in accordance with Equation 2 below.

$$\\ \begin{matrix}{\tilde{z}}_{0} , … , {\tilde{z}}_{K - 1} = {π}_{1}^{- 1} ( {z}_{0} , … , {z}_{K - 1} ) & ( 2 )\end{matrix}$$

The wireless communication device may invert an interleaver π₁ to obtain the inverse interleaver π₁⁻¹(⋅). In some examples, the interleaver π₁ may be designed based on a CRC polynomial. For example, the interleaver π₁ may be based on a CRC polynomial for a 5G New Radio (NR) PDCCH. In such cases, the wireless communication device may determine the interleaver π₁ by removing indices associated with CRC bits from an interleaver for 5G polar coding. The wireless device may compute the CRC bits 335 using the first set of inverted bits \tilde{z} in accordance with an encoding constraint (e.g., the CRC polynomial). The wireless device may insert the CRC bits 335 after performing the first polar transform 305-a. For example, the wireless device may insert the CRC bits 335 in the second domain (e.g., the Z domain). In some examples, the wireless communication device may insert the CRC bits 335 such that the CRC bits 335 do not impact systematic encoding.

Similar to the first polar transform 305-a, the wireless communication device may map the first set of transformed bits z and the L CRC bits to indices of an intermediate domain vector associated with the second polar transform 305-b. The indices of the intermediate domain vector may correspond to indices of the L+K most reliable bit channels for the second polar transform 305-b. In some examples, the wireless communication device may sequentially map the L CRC bits to the first L indices of the intermediate domain vector. For example, the wireless communication device may order the first set of transformed bits z and the L CRC bits such that the L CRC bits precede the first set of transformed bits z in the intermediate domain vector.

The wireless communication device may apply the second polar transform 305-b after inserting the CRC bits 335. In some examples, the wireless communication device may generate the set of encoded bits 315 by applying the second polar transform 305-b to the intermediate domain vector (which includes the L CRC bits and the first set of transformed bits z). For example, the wireless communication device may provide the intermediate domain vector as an input to a second generation matrix to generate the set of encoded bits 315. The wireless communication device may transmit the set of encoded bits 315 (e.g., to another wireless communication device, to a decoding device).

A decoder, such as a decoder at a decoding device receiving the set of encoded bits 315 generated via the systematic polar coding procedure 400, may perform SCL decoding and check CRC in the second domain. For example, to check CRC in the second domain, the decoding device may apply the second polar transform 305-b to the set of encoded bits 315 to generate the intermediate domain vector (e.g., via SCL decoding). The decoder may be an example of the systematic polar decoder 220 at the wireless device 205-b as described with reference to FIG. 2.

The decoding device may decode a portion of the intermediate domain vector before terminating decoding of the intermediate domain vector. For example, the decoding device may decode the portion of the intermediate domain vector that includes the L CRC bits. After decoding the L CRC bits, the decoding device may perform SCL decoding to decode each of the first set of transformed bits z. If the decoding device determines that a bit from the first set of transformed bits z does not satisfy a decoding constraint (e.g., the CRC constraint), the decoding device may refrain from decoding the remainder of the first set of transformed bits z. Additionally, the decoding device may refrain from performing the first polar transform 305-a to convert the first set of transformed bits z back into the information bits 330. As such, the decoding device may not convert the intermediate domain vector from the second domain to the first domain, which may save power at the decoding device.

In an example, the decoding device may receive a set of encoded bits 315 that include a 5G 24-bit CRC polynomial and interleaver, where K=140. In such examples, the first CRC bit of the 24-bit CRC polynomial is determined using the first 65 bits of the corresponding interleaver. Accordingly, the decoding device may terminate decoding of the intermediate domain vector, at the earliest, at the 65th information bit (e.g., after the 65th information bit and the 24-bit CRC polynomial).

FIG. 4 shows an example of a systematic polar coding procedure 400 that supports systematic polar code using distributed cyclic redundancy check coding. The systematic polar coding procedure 400 may implement, or be implemented by, aspects of the wireless communications system 100, the signaling configuration 200, or both. For example, the systematic polar coding procedure 400 may be implemented by a wireless device, such as the wireless device 205-a as described with reference to FIG. 2. In some examples, the wireless device may perform a first polar transform 405-a on a set of data bits 410 to generate a first set of transformed bits. The wireless device may perform a second polar transform 405-b on the first set of transformed bits to calculate a set of encoded bits 415.

As used herein, bits prior to the first polar transform 405-a (e.g., pre-transformed bits, the set of data bits 410) may belong to a first domain (e.g., the U domain). Bits in between the first polar transform 405-a and the second polar transform 405-b may belong to a second domain (e.g., the Z domain). Finally, bits after both the first polar transform 405-a and the second polar transform 405-b (e.g., the set of encoded bits 415) may belong to a third domain (e.g., the X domain). The set of data bits 410 may include one or more frozen bits 420, one or more zero bits 425, and one or more information bits 430, and the set of encoded bits 415 may include one or more frozen bits 420, one or more parity bits 435, and one or more information bits 430. For example, a bit sequence u₀, u₁, u_{K-1} may correspond to information bits 430. In the example of FIG. 4, a wireless device may compute the parity bits 435 based on the first set of transformed bits.

The wireless device may apply the first polar transform 405-a to the set of data bits 410. For example, the wireless device may provide the set of data bits 410 as an input to a first generation matrix to generate the first set of transformed bits. To apply the first polar transform 405-a, the wireless communication device may identify bit channels and map the set of data bits 410 (e.g., the frozen bits 420, the zero bits 425, the information bits 430) to the identified bit channels. As used herein, “bit channels” may refer to or be used interchangeably with “bit locations.” In the example of FIG. 4, the wireless communication device may identify a first set of bit channels, A, of the multiple bit channels as bit channels having highest reliability levels for the first polar transform 405-a. The first set of bit channels may include a quantity K+L bit channels, where K may correspond to the quantity of information bits 430 and L may correspond to a quantity of parity bits 435.

The first set of bit channels may include information bit channels and parity bit channels. For example, the wireless communication device may select a first subset (e.g., one or more first bit channels) of the first set of bit channels to be information bit channels and select a second subset (e.g., one or more second bit channels) of the first set of bit channels to be parity bit channels, where B refers to the parity bit channels (e.g., to which parity bits are mapped to) and A refers to the first set of bit channels. The second subset, B, may correspond to a quantity of bit channels having smallest indices according to a natural ordering of indices of the multiple bit channels. In other words, a set B representing a subset of the set A to which parity bits 435 are to be mapped may include L bit channels (e.g., locations) with smallest indices in the set A. Alternatively, the second subset, B, may correspond to a quantity of bit channels having lowest reliability levels (e.g., according to the polar reliability sequence) in the first set of bit channels. A remaining set of bit channels (e.g., A), such as a second set of bit channels, may be frozen bit channels corresponding to frozen bits 420. For example, the second set of bit channels A including the frozen bit channels may correspond to bit channels having lowest reliability levels relative to the other bit channels.

The wireless communication device may map the information bits 430 to the first subset of the first set of bit channels corresponding to the information bit channels. For example, the wireless communication device may place the K information bits 430 in A\B (e.g., a subset of A including elements in A that are not in B) prior to the first polar transform 405-a (e.g., in a first domain). Additionally, the wireless communication device may set bits (e.g., zero bits 425 and frozen bits 420, respectively) in the second subset of the first set of bit channels (e.g., corresponding to the parity bit channels) and in the second set of bit channels (e.g., corresponding to the frozen bit channels) to zero prior to the first polar transform 405-a. In other words, the wireless communication device may set bits in A and B to zero.

The wireless communication device may apply the first polar transform 405-a to the bits mapped to the first set of bit channels and the second set of bit channels. For example, the wireless communication device may convert the bits from the first domain (e.g., a U domain) to a second domain (e.g., a Z domain) via the first polar transform 405-a. The bits transformed according to the first polar transform 405-a may be denoted as z (e.g., z₀, . . . , z_{K-1}). After performing the first polar transform 405-a, the wireless communication device may set the bits in the second set of bit channels (e.g., in Ā) to zero (e.g., insert zero bits 425). The bits in the first subset of the first set of bit channels (e.g., in A\B) may be unchanged after the first polar transform 405-a. As such, the first set of transformed bits in the z locations in set A\B after the polar transform are unchanged prior to the second polar transform 405-b.

A CRC code for a given quantity of information bits 430 (e.g., a payload size) may be represented by a parity check equation, represented as Equation 3 below.

$$\\ \begin{matrix}bS {}^{T} = 0 & ( 3 )\end{matrix}$$

The vector b may represent a combined payload comprising both CRC bits and information bits 430 prior to interleaving (e.g., prior to a dCRC interleaver). The parity check matrix S may be a binary matrix of size L×(K+L). To compute K+L CRC bits for a payload vector x of size K is equivalent to finding a CRC vector c such that Equation 4 below is satisfied.

$$\\ \begin{matrix}[ x , c ] \cdot {S}^{T} = 0 & ( 4 )\end{matrix}$$

In dCRC, the corresponding interleaver π may act on the columns of the matrix S. The parity check matrix after applying the interleaver π may be represented as S_{π}. In the example of FIG. 4, the wireless communication device may generate the set of parity bits v such that an encoding constraint is satisfied. In some cases, the encoding constraint may be a function of the set of parity bits v and the first set of transformed bits z. For example, the set of parity bits v may be calculated such that the combination of [v, z] satisfies a scalar condition (e.g., a threshold value). In some cases, the dCRC constraint may be a function satisfying the condition shown in Equation 5. Using the identity shown in Equation 6 below, Equation 5 may be rewritten as Equation 7 below.

$$\\ \begin{matrix}[ v , z ] {S}_{π}^{T} = 0 & ( 5 )\end{matrix}$$

$$\\ \begin{matrix}[ v , 0 ] {S}_{π}^{T} = [ 0 , z ] {S}_{π}^{T} = v & ( 6 )\end{matrix}$$

$$\\ \begin{matrix}v = [ 0 , z ] {S}_{π}^{T} {S}_{π , L}^{- 1} & ( 7 )\end{matrix}$$

The matrix

$$\\ {S}_{π , L}^{- 1}$$

may represent an inverse of the matrix obtained by taking the first L rows of the parity check matrix

$$\\ {S}_{π}^{T} .$$

The matrix

$$\\ {S}_{π , L}^{- 1}$$

may have a size of L×L. In some examples, the matrix

$$\\ {S}_{π , L}^{- 1}$$

may be computed offline and stored at the wireless communication device. In some examples, the complexity of computing the inverse matrix

$$\\ {S}_{π , L}^{- 1}$$

may be reduced due to the cyclic structure of the S_{π,L} matrix.

Similar to the first polar transform 405-a, the wireless communication device may map the first set of transformed bits z and the L parity bits to indices of an intermediate domain vector associated with the second polar transform 405-b. The indices of the intermediate domain vector may correspond to indices of the L+K most reliable bit channels for the second polar transform 405-b. In some examples, the wireless communication device may sequentially map the L CRC bits to the first L indices of the intermediate domain vector. As such, the wireless communication device may order the first set of transformed bits z and the L CRC bits such that the L CRC bits precede the first set of transformed bits z in the intermediate domain vector.

The wireless communication device may apply the second polar transform 305-b after inserting the parity bits 435. In some examples, the wireless communication device may generate the set of encoded bits 415 by applying the second polar transform 405-b to the intermediate domain vector (which includes the L parity bits and the first set of transformed bits z). For example, the wireless communication device may provide the intermediate domain vector as an input to a second generation matrix to generate the set of encoded bits 415. The wireless communication device may transmit the set of encoded bits 415 (e.g., to another wireless communication device, to a decoding device).

A decoder, such as a decoder at a device receiving the set of encoded bits 415 generated via the systematic polar coding procedure 400, may perform SCL decoding and check CRC in the second domain. For example, to check CRC in the second domain, the decoding device may apply the second polar transform 405-b to the set of encoded bits 415 to generate the intermediate domain vector. The decoder may be an example of the systematic polar decoder 220 at the wireless device 205-b as described with reference to FIG. 2.

The decoding device may decode a portion of the intermediate domain vector before terminating decoding of the intermediate domain vector. However, with reference to the examples discussed in FIG. 3, the decoding device of FIG. 4 may decode fewer bits of the intermediate domain vector to determine whether to terminate decoding. In such examples, because the set of parity bits v was calculated such that the intermediate domain vector that includes the set of parity bits v and the first set of transformed bits z satisfies a dCRC constraint, the decoding device may decode the intermediate domain vector as if it were a non-systemic polar code implementing dCRC.

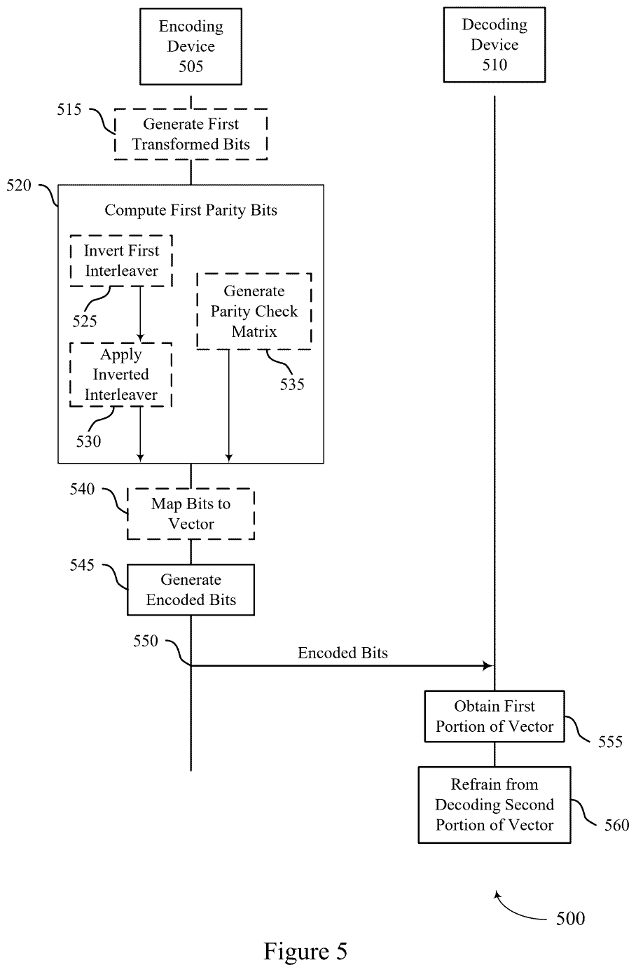

FIG. 5 shows an example of a process flow 500 that supports systematic polar code using distributed cyclic redundancy check coding. The process flow 500 may implement, or be implemented by, aspects of the wireless communications system 100, the signaling configuration 200, the systematic polar coding procedure 300, or the systematic polar coding procedure 400. For example, the process flow 500 may include an encoding device 505 and a decoding device 510, which may be examples of the wireless device 205-a or the wireless device 205-b as described with reference to FIG. 2. In the following description of the process flow 500, the operations between the encoding device 505 and the decoding device 510 may occur in a different order than the example order shown, or the operations performed by the encoding device 505 and the decoding device 510 may be performed in different orders or at different times. Some operations may also be omitted from the process flow 500, and other operations may be added to the process flow 500.

At 515, the encoding device 505 may generate, using a first polar transformation matrix, a first set of transformed bits based on a set of data bits. The set of data bits may include one or more frozen bits, one or more zero bits, and one or more information bits associated with a payload.

At 520, the encoding device 505 may compute, based on the first set of transformed bits, a first set of parity bits such that the first set of parity bits satisfy an encoding constraint. In some examples, the encoding constraint may include a CRC polynomial. Additionally, the first set of parity bits may include one or more CRC bits. In some other examples, the encoding constraint may include a function of the first set of parity bits and the first set of transformed bits, where satisfying the encoding constraint includes the function satisfying a scalar condition.

In some examples, to compute the first set of parity bits, at 525 the encoding device 505 may invert a first interleaver to obtain an inverted interleaver. In some examples, the first interleaver may be based on a CRC polynomial. For example, the first interleaver may be based on excluding indices associated with one or more CRC bits from a dCRC interleaver. Alternatively, the encoding device 505 may obtain the inverted interleaver (e.g., may store the inverted interleaver). At 530, the encoding device 505 may apply the inverted interleaver to the first set of transformed bits to generate a first set of inverted bits, wherein the first set of parity bits are based on the first set of inverted bits.

In some other examples, to compute the first set of parity bits, at 535 the encoding device 505 may generate a parity check matrix in accordance with an interleaver. In such cases, the first set of parity bits may be based on the parity check matrix, an inverted parity check matrix, and the first set of transformed bits. The inverted parity check matrix may include an inverted portion of the parity check matrix, where the inverted portion corresponds to a quantity associated with the first set of parity bits.

At 540, the encoding device 505 may map the first set of parity bits to first bit locations of an intermediate domain vector and the first set of transformed bits to second bit locations of the intermediate domain vector, the first bit locations preceding the second bit locations. In some examples, the intermediate domain vector may include the first set of parity bits in a first portion of the intermediate domain vector and the first set of transformed bits in a second portion of the intermediate domain vector. In some other examples, the intermediate domain vector may include the first set of parity bits interleaved with the first set of transformed bits. At 545, the encoding device 505 may generate, using a second polar transformation matrix, encoded bits based on the intermediate domain vector.

At 550, the encoding device 505 may transmit the encoded bits (e.g., a set of encoded bits). The decoding device 510 may receive a message including the set of encoded bits and may begin decoding the set of encoded bits using a first polar transformation matrix. In one example, the decoding device 510 may decode the set of encoded bits to obtain the first set of parity bits. The decoding device 510 may also decode a first portion of the first set of transformed bits. In some cases, the first portion of the first set of transformed bits may fail to satisfy the decoding constraint. In such cases, the decoding constraint may include a CRC polynomial and the first set of parity bits may include one or more CRC bits.

In some other examples, the decoding device 510 may decode the set of encoded bits to obtain the first portion of the first set of transformed bits. The decoding device 510 may also decode a first portion of the first set of parity bits corresponding to the first portion of the first set of transformed bits. In some cases, the first portion of the first set of transformed bits may fail to satisfy the decoding constraint. In such cases, the decoding constraint may include a function of the first set of parity bits and the first set of transformed bits, where satisfying the decoding constraint includes the function satisfying a scalar condition.

At 555, the decoding device 510 may decode the set of encoded bits to obtain a first portion of an intermediate domain vector using a first polar transformation matrix. In such examples, the intermediate domain vector may include the first set of parity bits and the first set of transformed bits, where the first set of transformed bits are associated with a payload of the message. In some examples, the first set of parity bits may include a first portion of the first portion of the intermediate domain vector and the first set of transformed bits may include a second portion of the first portion of the intermediate domain vector. In some other examples, the intermediate domain vector may include the first set of parity bits interleaved with the first set of transformed bits.

At 560, the decoding device 510 may refrain from decoding a second portion of the intermediate domain vector based on a first portion of the first set of transformed bits and at least a portion of the first set of parity bits failing to satisfy a decoding constraint. Additionally, the decoding device 510 may refrain from generating a decoded domain vector using a second polar transformation matrix and the intermediate domain vector based on the first set of transformed bits and at least the portion of the first set of parity bits failing to satisfy the decoding constraint.

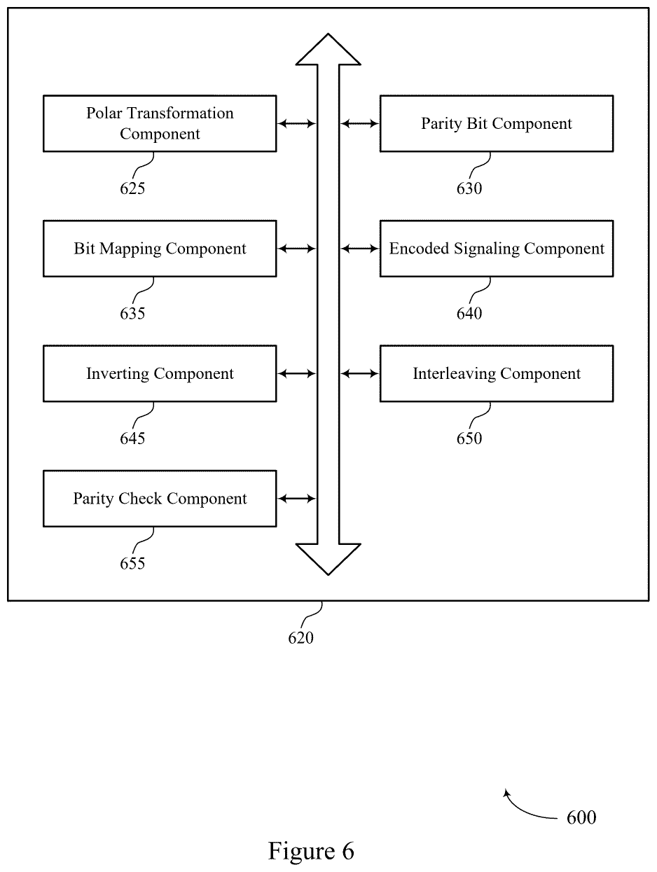

FIG. 6 shows an example of a processing system 620 that supports systematic polar code using distributed cyclic redundancy check coding. A processing system 620 may be an example of a processing system 140 (such as of an encoding device) and may include a polar transformation component 625, a parity bit component 630, a bit mapping component 635, an encoded signaling component 640, an inverting component 645, an interleaving component 650, a parity check component 655, or any combination thereof. A processing system 620, or various component thereof, may be an example of means for performing (such as a means for causing an encoding device to perform) various techniques described herein.

The polar transformation component 625 may be configured to cause the encoding device to generate, using a first polar transformation matrix, a first set of transformed bits based on a set of data bits. The parity bit component 630 may be configured to cause the encoding device to compute, based at least in part on the first set of transformed bits, a first set of parity bits such that the first set of parity bits satisfy an encoding constraint. The bit mapping component 635 may be configured to cause the encoding device to map the first set of parity bits to first bit locations of an intermediate domain vector and the first set of transformed bits to second bit locations of the intermediate domain vector, the first bit locations preceding the second bit locations. In some examples, the polar transformation component 625 may be configured to cause the encoding device to generate, using a second polar transformation matrix, encoded bits based on the intermediate domain vector. The encoded signaling component 640 may be configured to cause the encoding device to transmit the encoded bits.

In some examples, to support computing the first set of parity bits, the inverting component 645 may be configured to cause the encoding device to obtain an inverted interleaver (e.g., an inversion of a first interleaver, where the first interleaver is based on a cyclic redundancy check polynomial). For example, the inverting component 645 may compute the inverted interleaver from the first interleaver, or may store the inverted interleaver. In some examples, to support computing the first set of parity bits, the interleaving component 650 may be configured to cause the encoding device to apply the inverted interleaver to the first set of transformed bits to generate a first set of inverted bits, where the first set of parity bits are based on the first set of inverted bits.

In some examples, the first interleaver is based on excluding indices associated with one or more cyclic redundancy check bits from a distributed cyclic redundancy check interleaver.

In some examples, the encoding constraint includes a cyclic redundancy check polynomial and the first set of parity bits includes one or more cyclic redundancy check bits.

In some examples, the intermediate domain vector includes the first set of parity bits in a first portion of the intermediate domain vector and the first set of transformed bits in a second portion of the intermediate domain vector.

In some examples, to support computing the first set of parity bits, the parity check component 655 may be configured to cause the encoding device to generate a parity check matrix in accordance with an interleaver, where the first set of parity bits are based on the parity check matrix, an inverted parity check matrix, and the first set of transformed bits.

In some examples, the inverted parity check matrix includes an inverted portion of the parity check matrix, the inverted portion corresponding to a quantity associated with the first set of parity bits.

In some examples, the encoding constraint includes a function of the first set of parity bits and the first set of transformed bits. In some examples, satisfying the encoding constraint includes the function satisfying a scalar condition.

In some examples, the intermediate domain vector includes the first set of parity bits interleaved with the first set of transformed bits.

A processing system 620 may include or be a component of one or more chips, systems-on-chips (SoCs), chipsets, packages, components, or devices that individually or collectively constitute or include a processing system. A processing system 620 may interface with other components of a processing system 620. For example, operations described with reference to a processing system 620, or various components thereof, may be performed by or with other such components, including a receiver, a transmitter, a transceiver, a modem, a user interface, a modulator/demodulator, an encoder/decoder, or any combination thereof (such as of the processing system 620, coupled with the processing system 620, of a processing system 620).

By including or configuring a processing system 620 for operation in a processing system 620 as described herein, the processing system 620 may support techniques for reduced processing and reduced power consumption.

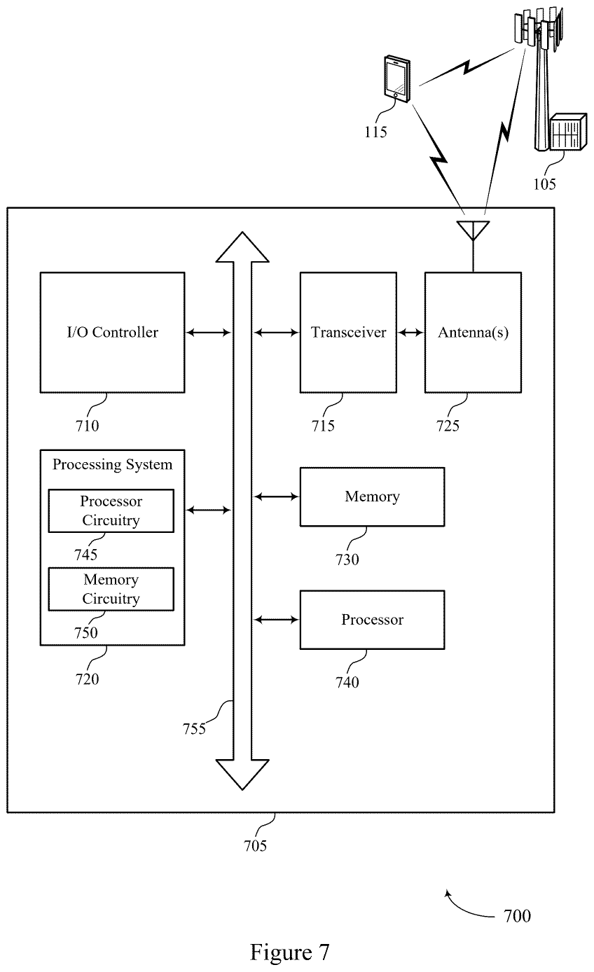

FIG. 7 shows an example of a system 700 including a device 705 that supports systematic polar code using distributed cyclic redundancy check coding. The device 705 may be an example of or include components of an encoding device, which may be an example of a UE 115, a network entity 105, or other similar devices described herein. The device 705 may communicate (such as wirelessly) with one or more other devices (such as network entities 105, UEs 115). The device 705 may include components for transmitting and receiving communication, which may include a processing system 720, an input/output (I/O) controller, such as an I/O controller 710, a transceiver 715, antenna(s) 725, a memory 730, and a processor 740. Components of the device 705 may be coupled (such as operatively, communicatively, functionally, electronically, electrically, in electronic communication) a bus 755.

The transceiver 715 may support bi-directional communication via antenna(s) 725, and may support transmission operations, reception operations, or both, as described herein. The transceiver 715 may implement functionality of a modem (such as a wireless modem) and may include one or more RF chains. An RF chain may include one or more filters, mixers, oscillators, amplifiers, analog-to-digital converters (ADCs), and other components that convert between an analog signal (such as for transmission or reception via an air interface) and a digital signal (such as for digital processing at the device 705). The transceiver 715 may modulate symbols and provide the modulated symbols to antenna(s) 725 for transmission, and demodulate symbols from signals received using antenna(s) 725.

The processor 740 may be a general-purpose processing component that supports various operations (such as applications) of the device 705. The memory 730 may be a general-purpose storage component that stores code executable by the processor 740. Such code may include instructions that, when executed by the processor 740, cause the device 705 to perform various functions (such as to support an application of the device 705). The I/O controller 710 may manage inputs and outputs for the device 705, may manage peripherals not integrated into the device 705, or may represent a physical connection (such as port) to an external peripheral. The processor 740 may interact with a modem, a keyboard, a mouse, a touchscreen, or other device (such as via I/O controller 710). In some implementations, a user may interact with the device 705 via the I/O controller 710 or via hardware components controlled by the I/O controller 710.

The processing system 720 may be an example of a processing system 140 or a processing system 600. For example, the processing system 720 may include processor circuitry 745 and memory circuitry 750 that stores code, and may be configured to cause the device 705 to perform operations that support systematic polar code using distributed cyclic redundancy check coding. Although the processing system 720 is illustrated as a separate component, which may involve a separate chip, chipset, or other module, in some implementations, one or more functions described with reference to the processing system 720 may be supported by or performed by a transceiver 715, antenna(s) 725, a processor 740, memory 730, or any combination thereof, such that a processing system 720 may include one or more of a transceiver 715, antenna(s) 725, a processor 740, memory 730, or any combination thereof.

By including or configuring the processing system 720 for operation in the device 705 as described herein, may support techniques for improved user experience related to reduced processing, reduced power consumption, and longer battery life.

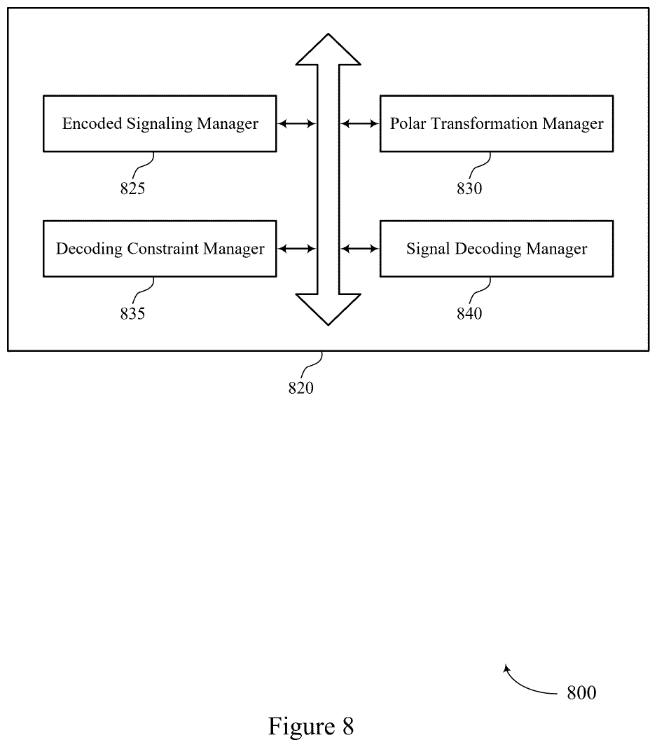

FIG. 8 shows an example of a processing system 820 that supports systematic polar code using distributed cyclic redundancy check coding. A processing system 820 may be an example of a processing system 145 (such as a decoding device) and may include an encoded signaling manager 825, a polar transformation manager 830, a decoding constraint manager 835, a signal decoding manager 840, or any combination thereof. A processing system 820, or various component thereof, may be an example of means for performing (such as a means for causing a decoding device to perform) various techniques described herein.

The encoded signaling manager 825 may be configured to cause the decoding device to receive a message including a set of encoded bits. The polar transformation manager 830 may be configured to cause the decoding device to decode the set of encoded bits to obtain a first portion of an intermediate domain vector using a first polar transformation matrix, the intermediate domain vector including a first set of parity bits and a first set of transformed bits, the first set of transformed bits associated with a payload of the message. The decoding constraint manager 835 may be configured to cause the decoding device to refrain from decoding a second portion of the intermediate domain vector based on a first portion of the first set of transformed bits and at least a portion of the first set of parity bits failing to satisfy a decoding constraint.

In some examples, to support decoding the set of encoded bits, the signal decoding manager 840 may be configured to cause the decoding device to decode the set of encoded bits to obtain the first set of parity bits. In some examples, to support decoding the set of encoded bits, the signal decoding manager 840 may be configured to cause the decoding device to decode the first portion of the first set of transformed bits, where the first portion of the first set of transformed bits fails to satisfy the decoding constraint.

In some examples, the decoding constraint includes a cyclic redundancy check polynomial and the first set of parity bits includes one or more cyclic redundancy check bits.

In some examples, the first set of parity bits including a first portion of the first portion of the intermediate domain vector and the first set of transformed bits include a second portion of the first portion of the intermediate domain vector.

In some examples, to support decoding the set of encoded bits, the signal decoding manager 840 may be configured to cause the decoding device to decode the set of encoded bits to obtain the first portion of the first set of transformed bits. In some examples, to support decoding the set of encoded bits, the signal decoding manager 840 may be configured to cause the decoding device to decode a first portion of the first set of parity bits corresponding to the first portion of the first set of transformed bits, where the first portion of the first set of transformed bits fails to satisfy the decoding constraint.

In some examples, the decoding constraint includes a function of the first set of parity bits and the first set of transformed bits. In some examples, satisfying the decoding constraint includes the function satisfying a scalar condition.

In some examples, the intermediate domain vector includes the first set of parity bits interleaved with the first set of transformed bits.

In some examples, the polar transformation manager 830 may be configured to cause the decoding device to refrain from generating a decoded domain vector using a second polar transformation matrix and the intermediate domain vector based on the first set of transformed bits and at least the portion of the first set of parity bits failing to satisfy the decoding constraint.

A processing system 820 may include or be an example of one or more chips, SoCs, chipsets, packages, components, or devices that individually or collectively constitute or include a processing system. A processing system 820 may interface with other components of a decoding device. For example, operations described with reference to a processing system 820, or various components thereof, may be performed by or with other such components, including a receiver, a transmitter, a transceiver, a modem, a user interface, a modulator/demodulator, an encoder/decoder, or any combination thereof (such as of the processing system 820, coupled with the processing system 820, of a decoding device). Operations described herein with reference to the processing system 820, or various components thereof, may be performed by or with other such components, including a CU 160, a DU 165, an RU 170, or any combination thereof. Each of one or more of any of such components, or subcomponents thereof (such as one or more processors, one or more memories), may communicate, directly or indirectly, with one another. The communication may include communication within a protocol layer of a protocol stack, communication associated with a logical channel of a protocol stack (such as between protocol layers of a protocol stack, within a device, component, or virtualized component associated with a decoding device, between devices, components, or virtualized components associated with a decoding device), or any combination thereof.

By including or configuring a processing system 820 for operation in a processing system 820 as described herein, the processing system 820 may support techniques for reduced processing and reduced power consumption.

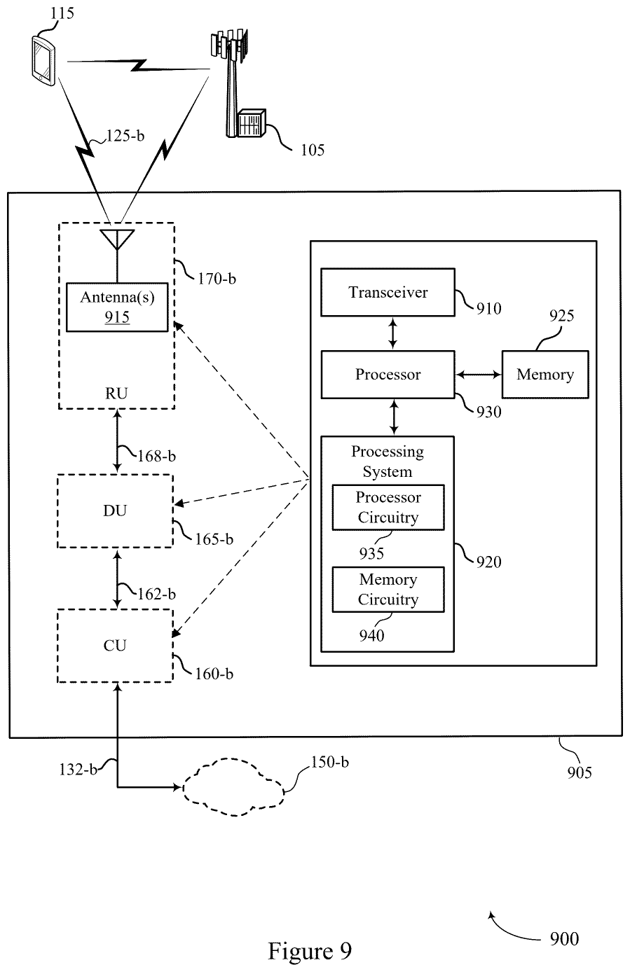

FIG. 9 shows an example of a system 900 including a device 905 that supports systematic polar code using distributed cyclic redundancy check coding. The device 905 may be an example of a decoding device that may communicate (such as via one or more wired interfaces or one or more wireless interfaces) with other network devices or network equipment such as a core network 150-b, other network entities 105, UEs 115, or any combination thereof. The device 905 may include components for transmitting and receiving communication, which may include a processing system 920, a transceiver 910, antenna(s) 915, a memory 925, and a processor 930. Components of the device 905 may be coupled (such as operatively, communicatively, functionally, electronically, electrically, in electronic communication) via one or more interfaces.

The transceiver 910 may communicate bi-directionally with another transceiver via wired or wireless links, and may support transmission operations, reception operations, or both, as described herein. The transceiver 910 may include a modem to modulate and demodulate signals, to provide the modulated signals for transmission (such as via antenna(s) 915, via a wired interface), and to demodulate received signals (such as received via antenna(s) 915, received via a wired interface). The transceiver 910 may be operable to support communication via one or more communication links (such as a communication link 125-b, a backhaul link 132-b, a midhaul link 162-b, fronthaul link 168-b).

The processor 930 may be a general-purpose processing component that supports various operations (such as applications) of the device 905. The memory 925 may be a general-purpose storage component that stores code executable by the processor 930. Such code may include instructions that, when executed by the processor 930, cause the device 905 to perform various functions (such as to support an application of the device 905).

For examples in which the device 905 is a network entity 105 in a disaggregated architecture, one or more components of the device 905 may be located at one or more of a CU 160-b, a DU 165-b, or an RU 170-b, one or more of which may include aspects of the processing system 920, the processor 930, the memory 925, or the transceiver 910. Functions of the device 905 may be performed at different components or an operation may be divided between different components (such as different functions being supported by aspects of the CU 160-b, the DU 165-b, or the RU 170-b, the transceiver 910, the processor 930, the memory 925, the processing system 920, or any combination thereof). For example, the processing system 920 may be a component of one or more of the CU 160-b, the DU 165-b, or the RU 170-b. In some examples, interfaces between components of device 905 (such as CU 160-b, DU 165-b, RU 170-b) may support communication at a protocol layer or between protocol layers of a protocol stack.

In some examples, the processing system 920 may manage aspects of communication with the core network 150-b (such as via a backhaul link 132). For example, the processing system 920 may manage the transfer of data communication for UEs 115 with a gateway of the core network 150-b. In some examples, the processing system 920 may manage communication with one or more other network entities 105 and may include a controller or scheduler for controlling communication with UEs 115 (such as in cooperation with the one or more other network entities 105). In some examples, the processing system 920 may support an interface (such as X2 interface, Xn interface) to provide communication between network entities 105.

The processing system 920 may be an example of a processing system 145 or a processing system 800. For example, the processing system 920 may include processor circuitry 935 and memory circuitry 940 that stores code, and the processing system 920 may be configured to cause the device 905 to perform operations that support systematic polar code using distributed cyclic redundancy check coding. Although the processing system 920 is illustrated as a separate component, which may involve a separate chip, chipset, or other module, in some implementations, one or more functions described with reference to the processing system 920 may be supported by or performed by a transceiver 910, antenna(s) 915, a processor 930, memory 925, or any combination thereof, such that a processing system 920 may include one or more of a transceiver 910, antenna(s) 915, a processor 930, memory 925, or any combination thereof. Further, processor circuitry 935 and memory circuitry 940 each may be implemented at the device 905 in accordance with an aggregated architecture, or the processor circuitry 935 and the memory circuitry 940 may be implemented at one or more of a CU 160-b, a DU 165-b, or an RU 170-b in accordance with a disaggregated architecture.

By including or configuring the processing system 920 for operation in the device 905 as described herein, may support techniques for improved user experience related to reduced processing, reduced power consumption, and longer battery life.

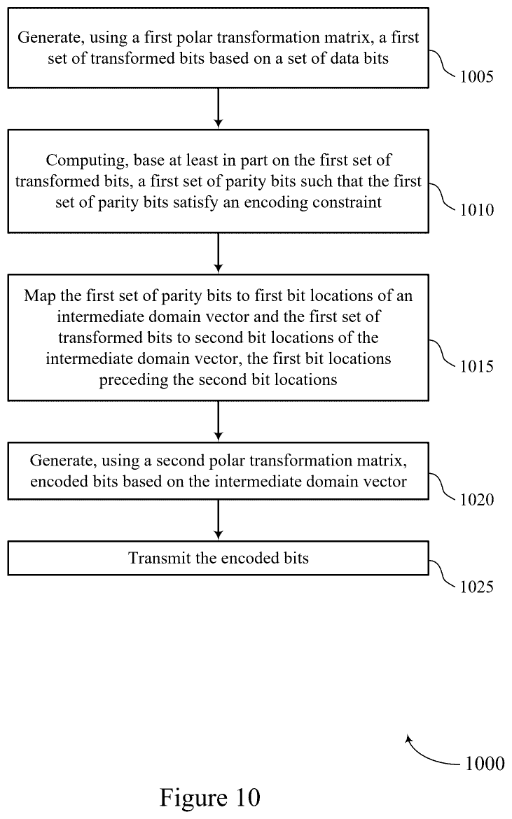

FIG. 10 shows an example of a method 1000 that supports systematic polar code using distributed cyclic redundancy check coding. Operations of the method 1000 may be performed by a UE or its components (such as using a processing system configured to cause the UE 115 to perform one or more of the operations) as described herein.

At 1005, the method may include generating, using a first polar transformation matrix, a first set of transformed bits based on a set of data bits. In some examples, aspects of the operations of 1005 may be performed by a polar transformation component 625.

At 1010, the method may include computing, based on the first set of transformed bits, a first set of parity bits such that the first set of parity bits satisfy an encoding constraint. In some examples, aspects of the operations of 1010 may be performed by a parity bit component 630.

At 1015, the method may include mapping the first set of parity bits to first bit locations of an intermediate domain vector and the first set of transformed bits to second bit locations of the intermediate domain vector, the first bit locations preceding the second bit locations. In some examples, aspects of the operations of 1015 may be performed by a bit mapping component 635.

At 1020, the method may include generating, using a second polar transformation matrix, encoded bits based on the intermediate domain vector. In some examples, aspects of the operations of 1020 may be performed by a polar transformation component 625.

At 1025, the method may include transmitting the encoded bits. In some examples, aspects of the operations of 1025 may be performed by an encoded signaling component 640.

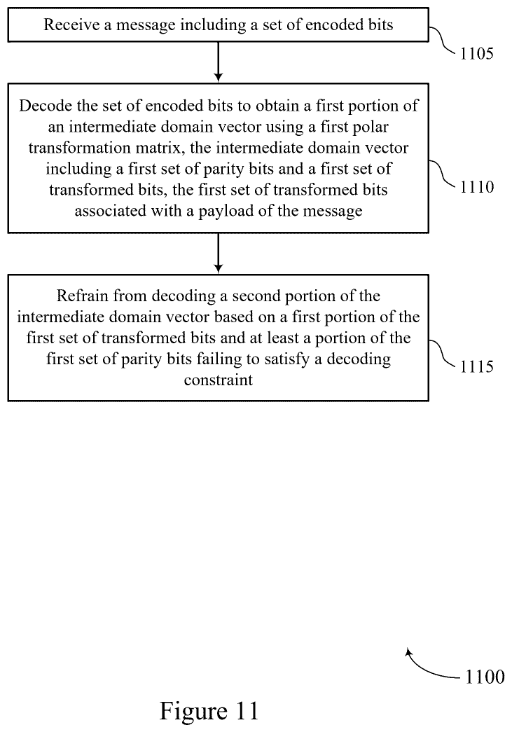

FIG. 11 shows an example of a method 1100 that supports systematic polar code using distributed cyclic redundancy check coding. Operations of the method 1100 may be performed by a network entity 105 or its components (such as using a processing system configured to cause the network entity to perform one or more operations) as described herein.

At 1105, the method may include receiving a message including a set of encoded bits. In some examples, aspects of the operations of 1105 may be performed by an encoded signaling manager 825.

At 1110, the method may include decoding the set of encoded bits to obtain a first portion of an intermediate domain vector using a first polar transformation matrix, the intermediate domain vector including a first set of parity bits and a first set of transformed bits, the first set of transformed bits associated with a payload of the message. In some examples, aspects of the operations of 1110 may be performed by a polar transformation manager 830.

At 1115, the method may include refrain from decoding a second portion of the intermediate domain vector based on a first portion of the first set of transformed bits and at least a portion of the first set of parity bits failing to satisfy a decoding constraint. In some examples, aspects of the operations of 1115 may be performed by a decoding constraint manager 835.

Aspect 1: A method for wireless communications at an encoding device, comprising: generating, using a first polar transformation matrix, a first set of transformed bits based at least in part on a set of data bits; computing, based at least in part on the first set of transformed bits, a first set of parity bits such that the first set of parity bits satisfy an encoding constraint; mapping the first set of parity bits to first bit locations of an intermediate domain vector and the first set of transformed bits to second bit locations of the intermediate domain vector, the first bit locations preceding the second bit locations; generating, using a second polar transformation matrix, encoded bits based at least in part on the intermediate domain vector; and transmitting the encoded bits.

Aspect 2: The method of aspect 1, wherein computing the first set of parity bits further comprises: applying an inverted interleaver to the first set of transformed bits to generate a first set of inverted bits, wherein the inverted interleaver is an inversion of a first interleaver, the first interleaver based at least in part on a cyclic redundancy check polynomial, and wherein the first set of parity bits are based at least in part on the first set of inverted bits.

Aspect 3: The method of aspect 2, wherein the first interleaver is based at least in part on excluding indices associated with one or more cyclic redundancy check bits from a distributed cyclic redundancy check interleaver.

Aspect 4: The method of any of aspects 2 through 3, wherein the encoding constraint comprises a cyclic redundancy check polynomial and the first set of parity bits comprises one or more cyclic redundancy check bits.

Aspect 5: The method of any of aspects 1 through 4, wherein the intermediate domain vector comprises the first set of parity bits in a first portion of the intermediate domain vector and the first set of transformed bits in a second portion of the intermediate domain vector.

Aspect 6: The method of any of aspects 1 through 5, wherein computing the first set of parity bits further comprises: generating a parity check matrix in accordance with an interleaver, wherein the first set of parity bits are based on the parity check matrix, an inverted parity check matrix, and the first set of transformed bits.

Aspect 7: The method of aspect 6, wherein the inverted parity check matrix comprises an inverted portion of the parity check matrix, the inverted portion corresponding to a quantity associated with the first set of parity bits.

Aspect 8: The method of any of aspects 6 through 7, wherein the encoding constraint comprises a function of the first set of parity bits and the first set of transformed bits, and satisfying the encoding constraint comprises the function satisfying a scalar condition.

Aspect 9: The method of any of aspects 1 through 8, wherein the intermediate domain vector comprises the first set of parity bits interleaved with the first set of transformed bits.

Aspect 10: A method for wireless communications at a decoding device, comprising: receiving a message comprising a set of encoded bits; decoding the set of encoded bits to obtain a first portion of an intermediate domain vector using a first polar transformation matrix, the intermediate domain vector comprising a first set of parity bits and a first set of transformed bits, the first set of transformed bits associated with a payload of the message; and refrain from decoding a second portion of the intermediate domain vector based at least in part on a first portion of the first set of transformed bits and at least a portion of the first set of parity bits failing to satisfy a decoding constraint.

Aspect 11: The method of aspect 10, wherein decoding the set of encoded bits comprises: decoding the set of encoded bits to obtain the first set of parity bits; and decoding the first portion of the first set of transformed bits, wherein the first portion of the first set of transformed bits fails to satisfy the decoding constraint.

Aspect 12: The method of aspect 11, wherein the decoding constraint comprises a cyclic redundancy check polynomial and the first set of parity bits comprises one or more cyclic redundancy check bits.

Aspect 13: The method of any of aspects 10 through 12, wherein the first set of parity bits comprising a first portion of the first portion of the intermediate domain vector and the first set of transformed bits comprise a second portion of the first portion of the intermediate domain vector.

Aspect 14: The method of any of aspects 10 through 13, wherein decoding the set of encoded bits comprises: decoding the set of encoded bits to obtain the first portion of the first set of transformed bits; and decoding a first portion of the first set of parity bits corresponding to the first portion of the first set of transformed bits, wherein the first portion of the first set of transformed bits fails to satisfy the decoding constraint.

Aspect 15: The method of aspect 14, wherein the decoding constraint comprises a function of the first set of parity bits and the first set of transformed bits, and satisfying the decoding constraint comprises the function satisfying a scalar condition.

Aspect 16: The method of any of aspects 10 through 15, wherein the intermediate domain vector comprises the first set of parity bits interleaved with the first set of transformed bits.

Aspect 17: The method of any of aspects 10 through 16, further comprising: refraining from generating a decoded domain vector using a second polar transformation matrix and the intermediate domain vector based at least in part on the first set of transformed bits and at least the portion of the first set of parity bits failing to satisfy the decoding constraint.

Aspect 18: An encoding device for wireless communications, comprising a processing system that includes processor circuitry and memory circuitry that stores code, the processing system configured to cause the encoding device to perform a method of any of aspects 1 through 9.

Aspect 19: An encoding device for wireless communications, comprising at least one means for performing a method of any of aspects 1 through 9.

Aspect 20: A non-transitory computer-readable medium storing code for wireless communications, the code comprising instructions executable by one or more processors to perform a method of any of aspects 1 through 9.

Aspect 21: A decoding device for wireless communications, comprising a processing system that includes processor circuitry and memory circuitry that stores code, the processing system configured to cause the decoding device to perform a method of any of aspects 10 through 17.

Aspect 22: A decoding device for wireless communications, comprising at least one means for performing a method of any of aspects 10 through 17.

Aspect 23: A non-transitory computer-readable medium storing code for wireless communications, the code comprising instructions executable by one or more processors to perform a method of any of aspects 10 through 17.

It should be noted that methods described herein describe possible implementations. Other implementations in accordance with the described techniques are possible, including implementations in which operations are rearranged or otherwise modified relative to the described methods. Further, aspects from two or more of the described methods may be combined.

Although aspects of 5G or 6G systems may be described for purposes of example and corresponding terminology may be used in the description, the techniques described herein are applicable beyond 5G, or 6G networks. For example, the described techniques may be applicable to other communication systems such as Institute of Electrical and Electronics Engineers (IEEE) 802.11 (Wi-Fi), IEEE 802.20, Flash-OFDM, or other systems and radio technologies not explicitly mentioned herein.

As used herein, a processing system (such as a processing system 140, a processing system 145) includes processor (or “processing”) circuitry in the form of one or multiple processors, microprocessors, processing units (such as central processing units (CPUs), graphics processing units (GPUs), neural processing units (NPUs) (also referred to as neural network processors or deep learning processors (DLPs)), or digital signal processors (DSPs)), processing blocks, application-specific integrated circuits (ASICs), programmable logic devices (PLDs), or other discrete gate or transistor logic or circuitry (any one or more of which may be generally referred to herein individually as a “processor” or collectively as “the processor” or “the processor circuitry”). Such processors may be individually or collectively configurable or configured to perform functions or operations described herein. A group of processors collectively configurable or configured to cause a device to perform a set of functions may include a first processor configured to cause the device to perform a first function of the set and a second processor configured to cause the device to perform a second function of the set. In some other examples, each of a group of processors may be configured to cause a device to perform a same set of functions.

As used herein, a processing system (such as a processing system 140, a processing system 145) also includes memory circuitry in the form of one or multiple memory devices, memory blocks, memory elements, or other discrete gate or transistor logic or circuitry, each of which may include or implement tangible storage media such as random-access memory (RAM) or read-only memory (ROM), or combinations thereof (any one or more of which may be generally referred to herein individually as a “memory” or collectively as “the memory” or “the memory circuitry”). One or more of the memories may be coupled (such as operatively, communicatively, electronically, electrically) with one or more processors of the processor circuitry and may individually or collectively store processor-executable code or instructions (such as software) that, when executed by one or more of the processors, may cause a device (such as configure the device, using one or more of the processors) to perform functions or operations described herein. Additionally, or alternatively, in some examples, one or more of the processors may be configured to cause a device to perform functions or operations described herein without requiring configuration by software. As used herein, “software” shall be construed to mean instructions, instruction sets, code, code segments, program code, programs, subprograms, software modules, applications, software applications, software packages, routines, subroutines, objects, executables, threads of execution, procedures, or functions, among other examples, whether referred to as software, firmware, middleware, microcode, hardware description language, or otherwise.

As used herein, a processing system (such as a processing system 140, a processing system 145) may include or be coupled with one or more modems (such as a cellular modem, a 5G-compliant modem, a 6G-compliant modem). In some examples, one or more processors of a processing system may include or implement one or more of the modems. A processing system also may include or be coupled with multiple radios (collectively “the radio”), multiple RF chains, or multiple transceivers, each of which may in turn be coupled with one or more of multiple antennas. In some examples, one or more processors of a processing system may include or implement one or more of the radios, RF chains, or transceivers. An RF chain may include one or more filters, mixers, oscillators, amplifiers, analog-to-digital converters (ADCs), or other devices that convert between an analog signal (such as for transmission or reception via an air interface) and a digital signal (such as for processing by processor circuitry).

As described herein, being “configured to,” being “configurable to,” and being “operable to” may be used interchangeably and may be associated with a capability, when executing code (such as processor-executable code, instructions) stored in memory circuitry (such as a non-transitory computer-readable medium, of the memory circuitry, storing code for wireless communication that is executable by a processing system) or otherwise, to perform one or more of the functions described herein.

As used herein, the term “determine” or “determining” can encompass one or more of a variety of actions. For example, “determining” can include one or more of calculating, computing, processing, deriving, detecting, estimating, looking up, inferring, ascertaining, measuring, resolving, selecting, obtaining, identifying, interpreting, demodulating, decoding, reading, establishing, forming, or generating, among other examples. In some such examples, determining can involve a processing system performing some type of calculating, computing, deriving, estimating, inferring, ascertaining, resolving, predicting, or other processing to obtain one or more numerical values, sets, elements, or other information or results. In some such examples, determining can involve a processing system identifying, looking up, investigating or otherwise obtaining some type of value, set, element, or other information or result from a table, data structure, database, or an implementation of memory, such as from a larger set of values, sets, or elements or other information or results. In some such examples, determining can involve a processing system identifying, interpreting, demodulating, decoding, detecting, reading, or otherwise obtaining some type of value, set, element, or other information or result signaled in, for example, a received wireless signal. In some such examples, determining can involve a processing system performing a measurement, such as on a received signal.

As used herein, the phrase “associated with” is intended to be interpreted in the inclusive sense, unless otherwise explicitly indicated. For example, the phrase “associated with” is not to be construed as a reference to a closed set of conditions, factors, criteria, elements, components or actions, among other examples. Specifically, unless a phrase refers to “associated with only ‘a,’” or the equivalent in context, whatever it is that is “associated with ‘a,’” may be associated with “a” alone or associated with a combination of “a” and one or more other conditions, factors, criteria, elements, components or actions, among other examples. The phrase “associated with” may be interpreted to mean or be interchanged with “in association with,” “in accordance with,” “based on,” “based at least in part on,” “as a function of,” “in response to,” “responsive to,” “using,” “coupled with,” in communication with,” “configured with,” “included with,” or “in cooperation with,” as appropriate in the relevant context unless otherwise explicitly indicated. Additionally, the use of such phrases does not indicate that what follows the phrase is the focal point or primary factor associated with the limitation preceding the phrase.

As used herein, a phrase referring to “at least one of” or “one or more of” a list of items refers to any combination of those items, including single members. For example, “at least one of: a, b, or c” is intended to cover: a, b, c, a-b, a-c, b-c, and a-b-c. Additionally, as used herein, a phrase referring to “a” or “an” element refers to one or more of such elements acting individually or collectively to perform the recited function(s). Thus, the terms “a,” “at least one,” “one or more,” and “at least one of one or more” may be interchangeable. For instance, for a claim that refers to “a” component performing one or more functions, each of the individual functions may be performed by a single component or by any combination of multiple components, and subsequent reference to a component introduced with the article “a” using the term “the” may refer to any or all of the single or multiple components. Thus, a component introduced with the article “a” may be understood to mean “one or more” components, and referring to “the” component subsequently in the claims may be understood to be equivalent to referring to “at least one of the one or more” components. Additionally, as used herein, a “set” can refer to one or more items, and a “subset” can refer to a whole set or less than the whole set, but not an empty set. Additionally, as used herein, the term “or” is intended to be interpreted in the inclusive sense, such as when referring to a series, and may be used interchangeably with the term “and/or,” unless otherwise explicitly indicated (for example, if used in conjunction with “either” or “only one of”). For example, “a or b” may include a only, b only, or a combination of a and b.

The disclosure is provided to enable a person having ordinary skill in the art to implement the described techniques. Modifications to the disclosure will be apparent to a person having ordinary skill in the art, and the techniques disclosed herein may be applied with other variations without departing from the scope of the disclosure. Thus, the disclosure is not limited to the examples and designs described herein but is to be accorded the broadest scope consistent with the principles and novel features disclosed herein.

What is claimed is:

1. An encoding device, comprising:
a processing system that includes processor circuitry and memory circuitry that stores code, the processing system configured to cause the encoding device to:
generate, using a first polar transformation matrix, a first set of transformed bits based at least in part on a set of data bits;
compute, based at least in part on the first set of transformed bits, a first set of parity bits such that the first set of parity bits satisfy an encoding constraint;
map the first set of parity bits to first bit locations of an intermediate domain vector and the first set of transformed bits to second bit locations of the intermediate domain vector, the first bit locations preceding the second bit locations;
generate, using a second polar transformation matrix, encoded bits based at least in part on the intermediate domain vector; and
transmit the encoded bits.

2. The encoding device of claim 1, wherein, to compute the first set of parity bits, the processing system is further configured to cause the encoding device to:
apply an inverted interleaver to the first set of transformed bits to generate a first set of inverted bits, wherein the inverted interleaver is an inversion of a first interleaver, the first interleaver based at least in part on a cyclic redundancy check polynomial, and wherein the first set of parity bits are based at least in part on the first set of inverted bits.

3. The encoding device of claim 2, wherein the first interleaver is based at least in part on excluding indices associated with one or more cyclic redundancy check bits from a distributed cyclic redundancy check interleaver.

4. The encoding device of claim 2, wherein the encoding constraint comprises a cyclic redundancy check polynomial and the first set of parity bits comprises one or more cyclic redundancy check bits.

5. The encoding device of claim 1, wherein the intermediate domain vector comprises the first set of parity bits in a first portion of the intermediate domain vector and the first set of transformed bits in a second portion of the intermediate domain vector.

6. The encoding device of claim 1, wherein, to compute the first set of parity bits, the processing system is further configured to cause the encoding device to:
generate a parity check matrix in accordance with an interleaver, wherein the first set of parity bits are based at least in part on the parity check matrix, an inverted parity check matrix, and the first set of transformed bits.

7. The encoding device of claim 6, wherein the inverted parity check matrix comprises an inverted portion of the parity check matrix, the inverted portion corresponding to a quantity associated with the first set of parity bits.

8. The encoding device of claim 6, wherein:
the encoding constraint comprises a function of the first set of parity bits and the first set of transformed bits, and
satisfying the encoding constraint comprises the function satisfying a scalar condition.

9. The encoding device of claim 1, wherein the intermediate domain vector comprises the first set of parity bits interleaved with the first set of transformed bits.

10. A decoding device, comprising:
a processing system that includes processor circuitry and memory circuitry that stores code, the processing system configured to cause the decoding device to:
receive a message comprising a set of encoded bits;
decode the set of encoded bits to obtain a first portion of an intermediate domain vector using a first polar transformation matrix, the intermediate domain vector comprising a first set of parity bits and a first set of transformed bits, the first set of transformed bits associated with a payload of the message; and
refrain from decoding a second portion of the intermediate domain vector based at least in part on a first portion of the first set of transformed bits and at least a portion of the first set of parity bits failing to satisfy a decoding constraint.

11. The decoding device of claim 10, wherein, to decode the set of encoded bits, the processing system is configured to cause the decoding device to:
decode the set of encoded bits to obtain the first set of parity bits; and
decode the first portion of the first set of transformed bits, wherein the first portion of the first set of transformed bits fails to satisfy the decoding constraint.

12. The decoding device of claim 11, wherein the decoding constraint comprises a cyclic redundancy check polynomial and the first set of parity bits comprises one or more cyclic redundancy check bits.

13. The decoding device of claim 10, wherein the first set of parity bits comprising a first portion of the first portion of the intermediate domain vector and the first set of transformed bits comprise a second portion of the first portion of the intermediate domain vector.

14. The decoding device of claim 10, wherein, to decode the set of encoded bits, the processing system is configured to cause the decoding device to:
decode the set of encoded bits to obtain the first portion of the first set of transformed bits; and
decode a first portion of the first set of parity bits corresponding to the first portion of the first set of transformed bits, wherein the first portion of the first set of transformed bits fails to satisfy the decoding constraint.

15. The decoding device of claim 14, wherein:
the decoding constraint comprises a function of the first set of parity bits and the first set of transformed bits, and
satisfying the decoding constraint comprises the function satisfying a scalar condition.

16. The decoding device of claim 10, wherein the intermediate domain vector comprises the first set of parity bits interleaved with the first set of transformed bits.

17. The decoding device of claim 10, wherein the processing system is further configured to cause the decoding device to:
refrain from generating a decoded domain vector using a second polar transformation matrix and the intermediate domain vector based at least in part on the first set of transformed bits and at least the portion of the first set of parity bits failing to satisfy the decoding constraint.

18. A method for wireless communications at an encoding device, comprising:
generating, using a first polar transformation matrix, a first set of transformed bits based at least in part on a set of data bits;
computing, based at least in part on the first set of transformed bits, a first set of parity bits such that the first set of parity bits satisfy an encoding constraint;
mapping the first set of parity bits to first bit locations of an intermediate domain vector and the first set of transformed bits to second bit locations of the intermediate domain vector, the first bit locations preceding the second bit locations;
generating, using a second polar transformation matrix, encoded bits based at least in part on the intermediate domain vector; and
transmitting the encoded bits.

19. The method of claim 18, wherein computing the first set of parity bits further comprises:
applying an inverted interleaver to the first set of transformed bits to generate a first set of inverted bits, wherein the inverted interleaver is an inversion of a first interleaver, the first interleaver based at least in part on a cyclic redundancy check polynomial, and wherein the first set of parity bits are based at least in part on the first set of inverted bits.

20. The method of claim 19, wherein the first interleaver is based at least in part on excluding indices associated with one or more cyclic redundancy check bits from a distributed cyclic redundancy check interleaver.

21. The method of claim 19, wherein the encoding constraint comprises a cyclic redundancy check polynomial and the first set of parity bits comprises one or more cyclic redundancy check bits.

22. The method of claim 18, wherein the intermediate domain vector comprises the first set of parity bits in a first portion of the intermediate domain vector and the first set of transformed bits in a second portion of the intermediate domain vector.

23. The method of claim 18, wherein computing the first set of parity bits further comprises:
generating a parity check matrix in accordance with an interleaver, wherein the first set of parity bits are based at least in part on the parity check matrix, an inverted parity check matrix, and the first set of transformed bits.

24. The method of claim 23, wherein the inverted parity check matrix comprises an inverted portion of the parity check matrix, the inverted portion corresponding to a quantity associated with the first set of parity bits.

25. The method of claim 23, wherein:
the encoding constraint comprises a function of the first set of parity bits and the first set of transformed bits, and
satisfying the encoding constraint comprises the function satisfying a scalar condition.

26. The method of claim 18, wherein the intermediate domain vector comprises the first set of parity bits interleaved with the first set of transformed bits.

27. A method for wireless communications at a decoding device, comprising:
receiving a message comprising a set of encoded bits;
decoding the set of encoded bits to obtain a first portion of an intermediate domain vector using a first polar transformation matrix, the intermediate domain vector comprising a first set of parity bits and a first set of transformed bits, the first set of transformed bits associated with a payload of the message; and
refrain from decoding a second portion of the intermediate domain vector based at least in part on a first portion of the first set of transformed bits and at least a portion of the first set of parity bits failing to satisfy a decoding constraint.

28. The method of claim 27, wherein decoding the set of encoded bits comprises:
decoding the set of encoded bits to obtain the first set of parity bits; and
decoding the first portion of the first set of transformed bits, wherein the first portion of the first set of transformed bits fails to satisfy the decoding constraint.

29. The method of claim 27, wherein decoding the set of encoded bits comprises:
decoding the set of encoded bits to obtain the first portion of the first set of transformed bits; and
decoding a first portion of the first set of parity bits corresponding to the first portion of the first set of transformed bits, wherein the first portion of the first set of transformed bits fails to satisfy the decoding constraint.

30. The method of claim 27, further comprising:
refraining from generating a decoded domain vector using a second polar transformation matrix and the intermediate domain vector based at least in part on the first set of transformed bits and at least the portion of the first set of parity bits failing to satisfy the decoding constraint.
